(19) United States
(12) Patent Application Publication
(10) Pub. No.: US 2026/0365845 A1
(43) Pub. Date: Nov. 19, 2026

(54) Hydrocarbon Material for 3D Printing and Pre-Structuring

(71) Applicant: ARXADA AG, Visp (CH)

(72) Inventors: Eva Kirchner, Visp (CH); Carla Tomas Kohlberg, Visp (CH); Gaetano La Delfa, Visp (CH); Flavio Kieliger, Visp (CH); Magnus Abgottspon, Visp (CH); Stefan Ellinger, Visp (CH); Jean Fournier, Visp (CH); Ulrich Mayerhoeffer, Visp (CH); Heinrich Schulte, Visp (CH)

(21) Appl. No.: 19/487,128

(22) PCT Filed: May 28, 2024
(86) PCT No.: PCT/EP2024/064577

§ 371 Date: Nov. 24, 2025

(30) Foreign Application Priority Data
Jun. 2, 2023 (EP) 23176954.8

(51) Int. Cl. C08L 65/00; B33Y 70/00; C08F 2/50; C08F 283/00; C08G 61/02; G03F 7/038; G03F 7/20

(52) U.S. Cl. CPC C08L 65/00; C08F 2/50; C08F 283/00; C08G 61/02; G03F 7/038; G03F 7/2002; B33Y 70/00

(57) ABSTRACT

The present invention relates to resin compositions, structures comprising said resin compositions, and the use of the inventive resin compositions as well as methods of manufacturing pre-structured objects comprising certain resin compositions.

### TECHNICAL FIELD

The present invention relates to resin compositions, structures comprising said resin compositions, and the use of the inventive resin compositions as well as a process for manufacturing pre-structured objects comprising certain resin compositions.

### TECHNOLOGICAL BACKGROUND

In the field of 3D printing and pre-structuring, resin compositions are used. In particular with regard to pre-structured objects, suitable resins are desired, which provide well-balanced properties with regard to workability, electronic properties (such as low dielectric constant and low dielectric loss), thermal properties (such as high glass transition temperature and low thermal shrinkage) and mechanic properties (such as tensile strength) and additionally are combinable with e.g. chip technology.

WO 2021/252728 discloses a hydrocarbon resin having a high glass transition temperature. However, suitable ready to use resin compositions having a high shelf stability for e.g. photo curing are still being needed.

Against this background, it is an object of the present invention to provide resin compositions, which are flexible in the field of application. It is a further object of the present invention to provide resin compositions that provide the possibility of at least two curing stages. It is a further object of the present invention to provide an efficient (e.g. fast) curing process. It is a further object of the present invention to provide a process of manufacturing cured parts such as pre-structured parts having well-balanced properties with regard to thermal properties, mechanic properties, and/or electronic properties. Finally, it is an object of the present invention to provide an easy access to manufacture the respective parts.

### SUMMARY OF THE INVENTION

In a first aspect, the present invention relates to a resin composition comprising
a) 20 to 99.99 wt % of a hydrocarbon resin composition comprising at least two of (A1) to (A3)
a.1) a hydrocarbon resin having a structure as defined by formula (A1)

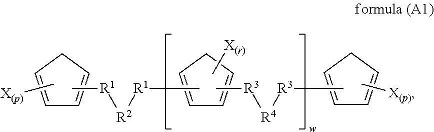

wherein
R¹ is independently a methylene group (CH₂) or a methylene group substituted with one or more —CH₃ or halogen,
R² is a bond or a substituted or unsubstituted C1-C20 alkylene,
R³ is independently a methylene group (CH₂) or a methylene group substituted with one or more —CH₃ or halogen,
R⁴ is independently a bond or a substituted or unsubstituted C1-C20 alkylene, C4-C20 aromatic group, or saturated or unsaturated C4-C20 cyclic group,
X is independently a functionality possessing at least one non-aromatic alkene, alkyne, C1-C14 alkyl, or an aromatic moiety,
p is independently an integer of 1 to 5,
r is independently 0 or an integer of 1 to 4, and
w is 0 or an integer of 1 to 50 and when w is 0, the bracket region represents a bond;
a.2) a hydrocarbon resin having a structure as defined by

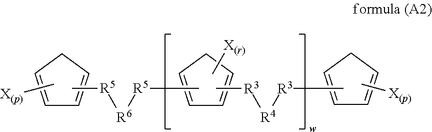

wherein
R³ is independently a methylene group (CH₂) or a methylene group substituted with one or more —CH₃ or halogen,
R⁴ is independently a bond or a substituted or unsubstituted C1-C20 alkylene, C4-C20 aromatic group, or saturated or unsaturated C4-C20 cyclic group,
R⁵ is independently a methylene group (CH₂) or a methylene group substituted with one or more —CH₃ or halogen,
R⁶ is a substituted or unsubstituted C4-C20 aromatic group or saturated or unsaturated C4-C20 cyclic group,
X is independently a functionality possessing at least one non-aromatic alkene, alkyne, C1-C14 alkyl, or an aromatic moiety,
p is independently an integer of 1 to 5,
r is independently 0 or an integer of 1 to 4, and
w is 0 or an integer of 1 to 50 and when w is 0, the bracket region represents a bond; and
a.3) a polymer, prepolymer, or oligomer derived from a hydrocarbon resin having a structure defined by formula

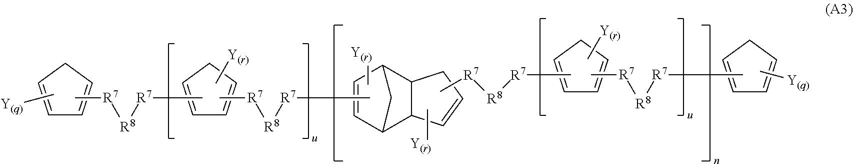

wherein
R⁷ is independently a methylene group (CH₂) or a methylene group substituted with one or more —CH₃ or halogen functionalities,
R⁸ is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety,
q is an integer of 1 to 5,
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
b) optionally 4.9 to 79.99 wt % of a monomer, oligomer, prepolymer, and/or polymer being polymerizable by exposure to actinic radiation or light (B1); and
c) 0.01 to 15 wt % of a catalyst (C),
each wt % based on the total weight of the resin composition.

According to a second aspect, the present invention relates to a process of curing the resin composition according to the first aspect comprising the step of heating and/or irradiating said resin composition.

According to a third aspect, the present invention relates to a cured resin obtainable by the process according to the second aspect.

According to a fourth aspect, the present invention relates to a 3D printing resin composition or a pre-structuring resin composition comprising the resin composition according to first aspect.

According to a fifth aspect, the present invention relates to a process for manufacturing a pre-structured object, the process comprising the steps of
a) providing a resin composition (RC) comprising
a.1) a hydrocarbon resin composition (HRC) comprising a hydrocarbon resin derived from a structure as defined by formula

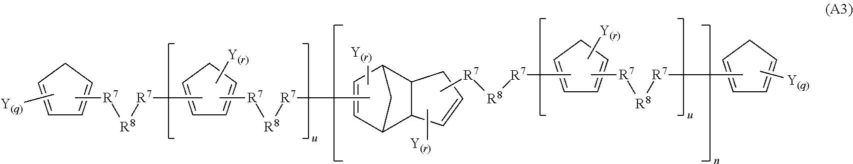

wherein
R⁷ is independently a methylene group (CH₂) or a methylene group substituted with one or more —CH₃ or halogen functionalities;
R⁸ is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety;
q is an integer of 1 to 5;
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
a.2) optionally a monomer, oligomer, prepolymer, and/or polymer being polymerizable by exposure to actinic radiation or light (B1); and
a.3) a photo initiator;
b) forming a resin composition layer having a thickness of 5 to 800 μm from the resin composition (RC);
c) irradiating the resin composition layer by means of a photomask providing a layer (L1), which at 25 °C it not soluble in a mixture of water and acetone;
d) washing the layer (L1) with a solvent (S2); and
e) curing the layer (L1) providing a layer (L2) having a Tg (determined by Tg onset via TMA measurement TMA) of more than 150 °C.

According to a sixth aspect, the present invention relates to pre-structured object obtained by the process according to the fifth aspect.

According to a seventh aspect, the present invention relates to the use of resin composition according to the first aspect in the manufacturing of a printed circuit board, a photo-sensitive build up film, a Photo-dielectric, a Die Attach Paste/Adhesive, a Die Attach Film Adhesive, a Capillary Underfill, a Molded Underfill, a Molding Compound, a Liquid Encapsulant, a Redistribution Dielectric, a ramome, a radar structures, a satellite structure, a antennas such as cellular phone antennas, satellite phone antennas, a antennas for 5G communication devices, a 3D printed copper clad laminate, a Resin-Coated-Copper (RCC) Lamination Processes, a light printing (DLP), a continuous liquid interface printing (CLIP), a Stereolithography (SL), a high-density interconnect (HDI) substrate, an integrated circuit (IC), a part of an underfill adhesive composition, or an adhesive in oil & gas applications (pipeline repair).

According to an eighth aspect, the present invention relates to a kit comprising
1) a container (A) comprising
a resin composition (RC) comprising
a.1) a hydrocarbon resin composition (HRC) comprising a hydrocarbon resin derived from a structure as defined by formula

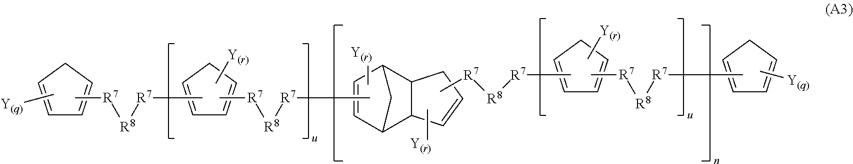

wherein
R⁷ is independently a methylene group (CH₂) or a methylene group substituted with one or more —CH₃ or halogen functionalities;
R^{a} is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety;
q is an integer of 1 to 5;
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
2) a container (B) comprising a monomer, oligomer, prepolymer, and/or polymer being polymerizable by exposure to actinic radiation or light (B1);
3) optionally a container (C); and
wherein the kit further comprises a catalyst (C), which is comprised in container (A), container (B), and/or container (C).

The inventors of the present invention surprisingly found that at least one of the above objects can be achieved by the cyclopentadiene based resin as disclosed herein. In this connection, the present invention e.g. provides a time-efficient (fast curing) method for producing 3D printed and pre-structured parts having well balanced properties with regards to e.g. Tg, mechanic properties, and/or electronic properties.

### DETAILED DESCRIPTION OF PREFERRED EMBODIMENTS

In the following, the invention will be explained in more detail.

The terms “about” in the context of the present invention denotes an interval of accuracy that a person skilled in the art will understand to still ensure the technical effect of the feature in question.

The term typically indicates a deviation from the indicated numerical value of ±10%, preferably ±5%, more preferably ±2%, and in particular ±1%.

As used herein, the articles “a” and “an” preceding an element or component are intended to be nonrestrictive regarding the number of instances (i.e. occurrences) of the element or component.

Therefore, “a” or “an” is to be read to include one or at least one, and the singular word form of the element or component also includes the plural unless the number is obviously meant to be singular.

The organic moieties mentioned in the above definitions of the variables are—like the term halogen—collective terms for individual listings of the individual group members. The prefix Cn-Cm indicates in each case the possible number of carbon atoms in the group.

The term “halogen” as used herein refers to fluorine, chlorine, bromine, or iodine, preferably fluorine, chlorine, or bromine.

The term “substituted bisimide” as used herein refers to compounds with substitutions at the C═C double bond (3 and/or 4 position) of the maleimide-group.

The term “alkyl” (either alone or as part of a larger group, such as alkoxy) as used herein denotes in each case a linear (i.e. straight-chain) or branched saturated hydrocarbon group having usually from 1 to 20 carbon atoms, preferably 1 to 10, or 1 to 6, or 1 to 4 carbon atoms, more preferably 1 to 3 or 1 to 2 or 1 carbon atoms. Examples of an alkyl group are methyl, ethyl, n-propyl, iso-propyl, n-butyl, 2-butyl, iso-butyl, tert-butyl, n-pentyl, 1-methylbutyl, 2-methylbutyl, 3-methyl-butyl, 2,2-dimethylpropyl, 1-ethylpropyl, n-hexyl, 1,1-dimethylpropyl, 1,2-dimethylpropyl, 1-methylpentyl, 2-methylpentyl, 3-methylpentyl, 4-methylpentyl, 1,1-dimethylbutyl, 1,2-dimethyl-butyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, 1-ethyl-2-methylpropyl, and the like.

The term “alkenyl” (either alone or as part of a larger group, e.g. alkenyloxy) as used herein denotes in each case a linear (i.e. straight-chain) or branched hydrocarbon group having usually from 2 to 20 carbon atoms, frequently from 2 to 10, 2 to 6, or 2 to 4 carbon atoms, with one or more C═C double bonds. The alkenyl moieties, where appropriate, can be of either the (E)- or (Z)-configuration.

“Alkynyl” substituents (also referred to as “alkyne”; either alone or as part of a larger group, e.g. alkynyloxy) as used herein denotes in each case a linear (i.e. straight-chain) or branched hydrocarbon group having usually from 2 to 20 carbon atoms, frequently from 2 to 10, 2 to 6, or 2 to 4 carbon atoms, with one or more C≡C triple bonds.

The term “alkoxy” as used herein denotes in each case alkyl substituents as defined above that are connected to another structural moiety via an oxygen atom (—O—). Exemplary alkoxy groups are methoxy, trifluoromethoxy, ethoxy, 2,2,2-trifluoroethoxy, n-propoxy, iso-propoxy, n-butoxy, sec-butoxy, tert-butoxy, n-pentoxy.

The term “aryl” (either alone or as part of a larger group, such as e.g. aryloxy, aralkyl) as used herein refers to aromatic ring systems (i.e. fulfilling the Hückel rule—having (4n+π2) electrons, with n being 0 or an integer of preferably 1 to 3) which can be in mono-, bi- or tricyclic form. Examples of such rings include phenyl, naphthyl, anthracenyl, indenyl or phenanthrenyl. Preferred aryl groups are phenyl and naphthyl, phenyl being most preferred.

The term “aromatic group” as used herein refers to a bivalent group comprising at least one aromatic ring system. An “aromatic group having between 1 and 20 carbon atoms” refers to a bivalent group having between 1 and 20 carbon atoms and comprising at least one aromatic ring system. The group may be fully aromatic, such as a phenylene, or may comprise at least two bivalent aromatic ring systems that are connected via a bond such as phenylene-phenylene.

The term “aralkyl” as used herein refers to an alkyl moiety as defined herein that is substituted by an aryl moiety as defined herein.

The term “alkenylaryl” as used herein refers to an aryl moiety as defined herein that is substituted by an alkenyl moiety as defined herein.

The term “alkylene” as used herein refers to a bivalent linear or branched alkyl group, e.g. —(CH2)x- or —CH(CH3)CH2-, wherein x is a positive integer of usually 1 to 20, preferably 1 to 10 or 1 to 5. In the context of the present invention “C1-C5-alkylene” refers to an alkylene moiety with 1, 2, 3, 4, and 5, respectively, carbon atoms, e.g. —CH2- groups; the term “alkylene”, however, not only comprises linear alkylene groups, i.e. “alkylene chains”, but branched alkylene groups, as well. The term “C1-C5-alkylene” refers to an alkylene moiety that is either linear, i.e. an alkylene chain, or branched and has 1, 2, 3, 4, or 5 carbon atoms.

It is to be understood that the alkylene, aromatic group, and cyclic group may “substituted or unsubstituted”. Exemplary substituents include hydroxy, carboxy, amino, sulfonyl, halogen, and phenyl-group. In one embodiment, the aforementioned moieties are not further substituted.

The term “polymer” as used herein encompasses copolymers and homopolymers.

It needs to be understood that the term “comprising” is not limiting. For the purposes of the present invention, the term “consisting of” is considered to be a preferred embodiment of the term “comprising of”. If hereinafter a group is defined to comprise at least a certain number of embodiments, this is also meant to encompass a group which preferably consists of these embodiments only.

As above-outlined, subject of the present invention is in a first aspect a resin composition comprising
a) 20 to 99.99 wt % of a hydrocarbon resin composition comprising at least two of (A1) to (A3)
a.1) a hydrocarbon resin having a structure as defined by formula (A1)

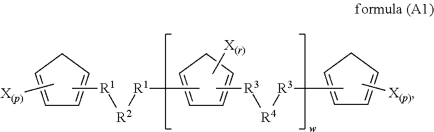

wherein
R¹ is independently a methylene group (CH₂) or a methylene group substituted with one or more —CH₃ or halogen,
R² is a bond or a substituted or unsubstituted C1-C20 alkylene,
R³ is independently a methylene group (CH₂) or a methylene group substituted with one or more —CH₃ or halogen,
R⁴ is independently a bond or a substituted or unsubstituted C1-C20 alkylene, C4-C20 aromatic group, or saturated or unsaturated C4-C20 cyclic group,
X is independently a functionality possessing at least one non-aromatic alkene, alkyne, C1-C14 alkyl, or an aromatic moiety,
p is independently an integer of 1 to 5,
r is independently 0 or an integer of 1 to 4, and
w is 0 or an integer of 1 to 50 and when w is 0, the bracket region represents a bond;
a.2) a hydrocarbon resin having a structure as defined by

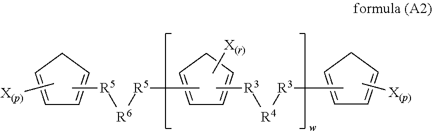

wherein
R³ is independently a methylene group (CH₂) or a methylene group substituted with one or more —CH₃ or halogen,
R⁴ is independently a bond or a substituted or unsubstituted C1-C20 alkylene, C4-C20 aromatic group, or saturated or unsaturated C4-C20 cyclic group,
R⁵ is independently a methylene group (CH₂) or a methylene group substituted with one or more —CH₃ or halogen,
R⁶ is a substituted or unsubstituted C4-C20 aromatic group or saturated or unsaturated C4-C20 cyclic group,
X is independently a functionality possessing at least one non-aromatic alkene, alkyne, C1-C14 alkyl, or an aromatic moiety,
p is independently an integer of 1 to 5,
r is independently 0 or an integer of 1 to 4, and
w is 0 or an integer of 1 to 50 and when w is 0, the bracket region represents a bond; and
a.3) a polymer, prepolymer, or oligomer derived from a hydrocarbon resin having a structure defined by formula (A3)

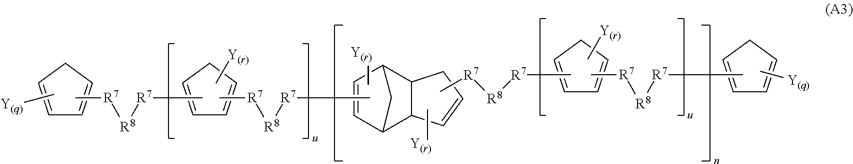

wherein
R⁷ is independently a methylene group (CH₂) or a methylene group substituted with one or more —CH₃ or halogen functionalities,
R⁸ is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety,
q is an integer of 1 to 5,
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
b) optionally 4.9 to 79.99 wt % of a monomer, oligomer, prepolymer, and/or polymer being polymerizable by exposure to actinic radiation or light (B1); and
c) 0.01 to 15 wt % of a catalyst (C),
each wt % based on the total weight of the resin composition.

The inventive composition surprisingly provides well-balanced properties, e.g. withstanding high thermal stress and/or shows excellent electronic properties.

In the following, particular embodiments of the present invention such as preferred moieties are described in further details. It is to be understood that each embodiment is relevant on its own as well as in combination with other embodiments.

The skilled person will understand that R¹, R², R³, R⁴, R⁵, R⁶, R⁷, and R⁸ are bivalent groups, i.e. that the respective groups have two binding sites to the remainder of the molecule.

In one embodiment, X and/or Y is independently vinylbenzyl, propenylbenzene, ethenylbenzene, (methyl)ethenylbenzene, styrenyl, allyl, propargyl, butenyl, or benzyl, preferably independently allyl or benzyl.

In one embodiment, X and/or Y is independently selected from the group consisting of

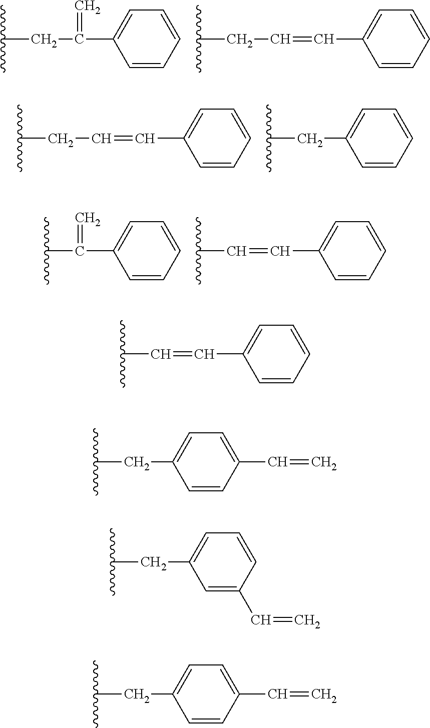

and isomers thereof.

In one embodiment, X and/or Y is independently selected from the group consisting of

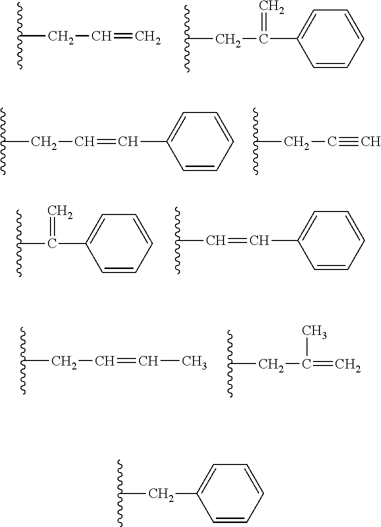

and isomers thereof.

In one embodiment, at least one X and/or Y is

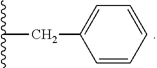 [SMILES: *Cc1ccccc1]

In one embodiment, X and/or Y is independently selected from the group consisting of

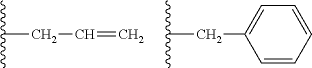

and isomers thereof.

In one embodiment, X and/or Y is independently C2-C20 alkenyl, C2-C20 alkynyl, or C8-C20 alkenylaryl, preferably C2-C12 alkenyl, C2-C12 alkynyl, or C8-C18 alkenylaryl, still more preferably C2-C8 alkenyl, C2-C8 alkynyl, or C8-C12 alkenylaryl, and in particular C2-C4 alkenyl or C8-C12 alkenylaryl.

In one embodiment,
R¹, R³, R⁵, and R⁷ are a methylene group (CH₂) and/or
R⁴ and R⁸ are independently a bond, a substituted or unsubstituted C6 aromatic group, a substituted or unsubstituted C10 aromatic group, or a substituted or unsubstituted C12 aromatic group.

Suitably, the substituted or unsubstituted C6 aromatic group is an unsubstituted phenylene or a phenylene substituted with e.g. hydroxyl and/or halogen (e.g. fluorine) such as tetrafluorophenylene.

Suitably, the substituted or unsubstituted C10 aromatic group is a substituted C10 aromatic group such as substituted with hydroxy and/or halogen (e.g. fluorine), preferably a bivalent naphthol.

Suitably, the substituted or unsubstituted C12 aromatic group is substituted or unsubstituted phenylene-phenylene.

In one embodiment, R² is a bond or a C1-C10 alkylene, preferably a bond or a C1-C5 alkylene, more preferably a bond or a C1-C2 alkylene, and in particular a bond.

In one embodiment, R⁶ is a substituted or unsubstituted C4-C18 aromatic group or a C4-C16 saturated or unsaturated cyclic group, preferably a substituted or unsubstituted C4-C16 aromatic group or a C4-C10 saturated or unsaturated cyclic group, more preferably a substituted or unsubstituted C6 aromatic group, a substituted or unsubstituted C10 aromatic group, a substituted or unsubstituted C12 aromatic group, a substituted or unsubstituted C13 aromatic group, a substituted or unsubstituted C14 aromatic group, a C5 saturated cyclic group, or a C6 saturated cyclic group, and in particular a substituted or unsubstituted C6 aromatic group, a substituted C10 aromatic group, or a C12 aromatic group.

In one embodiment, R⁶ is a substituted or unsubstituted C4-C16 saturated or unsaturated cyclic group, preferably a substituted or unsubstituted C4-C10 saturated or unsaturated cyclic group, more preferably a substituted or unsubstituted C5 saturated cyclic group or a substituted or unsubstituted C6 saturated cyclic group.

In one embodiment, w is 0 or an integer of 1 to 20, preferably wherein w is 0 or an integer of 1 to 5, and in particular wherein w is 0.

In one embodiment, p is an integer of 1 to 4, preferably of 1 to 3, more preferably of 1 or 2, and in particular 1.

In one embodiment, r is independently 0 or an integer of 1 to 3, more preferably 0, 1, or 2, and in particular 0 or 1.

In one embodiment, the hydrocarbon resin composition comprises
a.1) a hydrocarbon resin having a structure as defined by formula (A1) formula (A1).

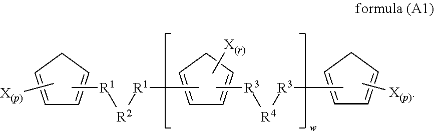

In one embodiment, the hydrocarbon resin composition comprises
a.1) a hydrocarbon resin having a structure as defined by formula (A1-1)

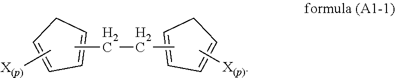

In one embodiment, the hydrocarbon resin composition comprises a.2) a hydrocarbon resin having a structure as defined by formula (A2)

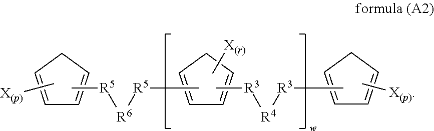

In one embodiment, the hydrocarbon resin composition comprises (A2), wherein R⁶ is a substituted C6 aromatic group or a substituted or unsubstituted C12 aromatic group, preferably wherein R⁵ is a methylene group (CH₂), more preferably wherein the hydrocarbon resin composition comprises
a.2) a hydrocarbon resin having a structure as defined by formula (A2-2)

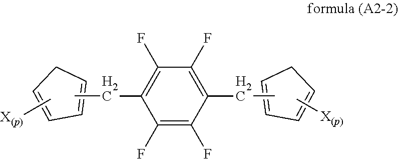

and/or
a hydrocarbon resin having a structure as defined by formula (A2-3)

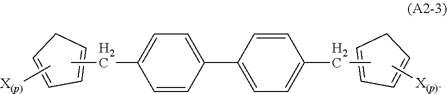

In this connection, it is to be understood that the hydrocarbon resin composition comprising (A2), wherein R⁶ is a substituted C6 aromatic group or a substituted or unsubstituted C12 aromatic group, can comprise at least one different hydrocarbon resin (A2) (wherein R⁶ is a substituted or unsubstituted C4-C20 aromatic group or saturated or unsaturated C4-C20 cyclic group) such as a hydrocarbon resin having a structure as defined by formula (A2-1).

In one embodiment, the hydrocarbon resin composition comprises
a.2) a hydrocarbon resin having a structure as defined by formula (A2-1)

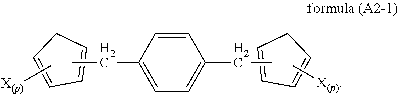

In one embodiment, the hydrocarbon resin composition comprises
a.2) a hydrocarbon resin having a structure as defined by formula (A2-2)

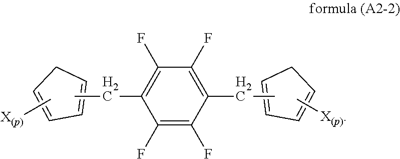

In one embodiment, the hydrocarbon resin composition comprises
a.2) a hydrocarbon resin having a structure as defined by formula (A2-3)

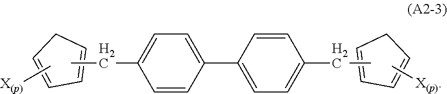

In one embodiment, the hydrocarbon resin composition comprises
a hydrocarbon resin having a structure as defined by formula (A2-1)

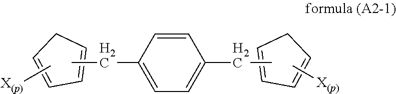

and
a hydrocarbon resin having a structure as defined by formula (A2-3)

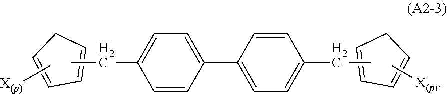

In one embodiment, the hydrocarbon resin composition comprises
a.3) a polymer, prepolymer, or oligomer derived from a hydrocarbon resin having a structure defined by formula (A3)

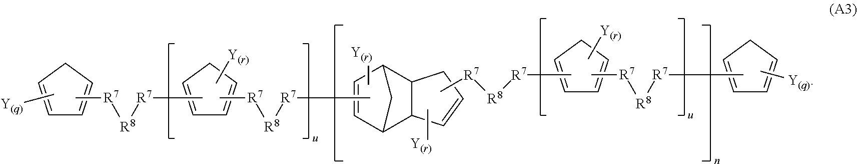

In one embodiment, the hydrocarbon resin composition comprises at least (A1) and (A2).

In one embodiment the hydrocarbon resin composition comprises at least two different hydrocarbon resin having a structure as defined by formula (A2). These at least two different hydrocarbon resin differ at least in one moiety (R³, R⁴, R⁵, R⁶, X, p, r, and w) and may be denoted as (A2-X) and (A2-Y). Suitably, the at least two different hydrocarbon resin may be a hydrocarbon resin having a structure as defined by formula (A2-1) and a hydrocarbon resin having a structure as defined by formula (A2-3). If present, the at least two different hydrocarbon resin (A2-X) and (A2-Y) generally have a weight ratio of 100:1 to 1:100, preferably of 50:1 to 1:15, more preferably of 10:1 to 1:10 such as of 4:1 to 1:4, or of 3:1 to 1:3, or of 2:1 to 1:2, or of 1.5:1 to 1:1.5, or of 1.2:1 to 1:1.2. In this connection, the hydrocarbon resin composition may additionally comprises (A1).

In one embodiment, the hydrocarbon resin composition comprises at least (A1) and a polymer, prepolymer, or oligomer derived from a hydrocarbon resin having a structure defined by formula (A3).

In one embodiment, the hydrocarbon resin composition comprises at least (A2) and a polymer, prepolymer, or oligomer derived from a hydrocarbon resin having a structure defined by formula (A3).

In one embodiment, the hydrocarbon resin composition comprises (A1), (A2), and a polymer, prepolymer, or oligomer derived from a hydrocarbon resin having a structure defined by formula (A3).

In one embodiment, the hydrocarbon resin composition comprises (A1), (A2-X), (A2-Y), and a polymer, prepolymer, or oligomer derived from a hydrocarbon resin having a structure defined by formula (A3).

In one embodiment, the polymer, prepolymer, or oligomer derived from a hydrocarbon resin having a structure defined by formula (A3) is present and wherein preferably
u is independently 0 or an integer of 1 to 200, preferably wherein u is 0 or an integer of 1 to 100, and in particular wherein u is 0 or an integer of 1 to 50; and/or
q is an integer of 1 to 4, preferably of 1 to 3, more preferably of 1 or 2, and in particular 1.

In one embodiment, the monomer, oligomer, prepolymer, and/or polymer being polymerizable by exposure to actinic radiation or light (B1) comprises reactive end groups selected from the group consisting of acrylates, methacrylates, olefins such as α-olefins, N-vinyls, acrylamides, methacrylamides, styrenics, epoxides, oxetans, thiols, 1,3-dienes, vinyl halides, acrylonitriles, vinyl esters, maleimides, bisnadicimides, vinyl ethers, cyanate esters, bisbenzocyclobutenes, and mixtures thereof.

In one embodiment, the monomer, oligomer, prepolymer, and/or polymer being polymerizable by exposure to actinic radiation or light (B1) comprises reactive end groups selected from the group consisting of acrylates, methacrylates, olefins, epoxides, oxetanes, maleimides, cyanate esters, bisbenzocyclobutenes, and mixtures thereof, and in particular selected from the group consisting of acrylates, methacrylates, olefins, epoxides, maleimides, cyanate esters, and mixtures thereof.

Suitable monomer, oligomer, prepolymer, and/or polymer being polymerizable by exposure to actinic radiation or light (B1) include butadiene based thermoplastic elastomers such as a styrene-butadiene copolymer (SBR:RICON-100, RICON-181, RICON-184, all manufactured by Cray Valley) and an acrylonitrile butadiene copolymer; and styrene-based thermoplastic elastomers such as a styrene-butadiene-styrene copolymer (SBS), a hydrogenated styrene-butadiene-styrene copolymer, a styrene-isoprene-styrene copolymer (SIS), a hydrogenated styrene-isoprene-styrene copolymer, and a hydrogenated styrene-(butadiene/isoprene)-styrene copolymer. One of these thermoplastic elastomers may be used alone, or two or more kinds thereof may be used in combination. Among these high molecular weight polymers, styrene-based thermoplastic elastomers such as a styrene-butadiene-styrene copolymer, a hydrogenated styrene-butadiene-styrene copolymer, a styrene-isoprene-styrene copolymer, a hydrogenated styrene-isoprene-styrene copolymer, and a hydrogenated styrene-(butadiene/isoprene)-styrene copolymer are preferred, and in particular, a styrene-isoprene-styrene copolymer, a hydrogenated styrene-butadiene-styrene copolymer, a hydrogenated styrene-isoprene-styrene copolymer, and a hydrogenated styrene-(butadiene/isoprene)-styrene copolymer are more preferred because they have higher heat resistance and are less likely to be oxidized and deteriorated. Specific examples thereof include SEPTON 1020, SEPTON 2002, SEPTON 2004F, SEPTON 2005, SEPTON 2006, SEPTON 2063, SEPTON 2104, SEPTON 4003, SEPTON 4044, SEPTON 4055, SEPTON 4077, SEPTON 4099, SEPTON 8004, SEPTON 8006, SEPTON 8007L, SEPTON HG252, SEPTON V9827, HYBRAR 7125 (hydrogenated), HYBRAR 7215F, and HYBRAR 7311F (all manufactured by Kuraray Co., Ltd.). In addition, the weight average molecular weight of the styrene-based thermoplastic elastomer is not particularly limited as long as it is 10,000 g/mol or more, but when it is too large, compatibility with a low molecular weight component having a weight average molecular weight of about 50 to 1,000 g/mol and an oligomer component having a weight average molecular weight of about 1,000 to 5,000 g/mol is deteriorated in addition to the polyphenylene ether compound, and it is difficult to ensure mixing and solvent stability. Therefore, the weight average molecular weight of the styrene-based thermoplastic elastomer is preferably about 10,000 to 300,000 g/mol.

In one embodiment, (B1) is an olefin and/or (meth)acrylate end group functionalized polyphenylene oxide resins, preferably a poly(p-phenylene oxide) (PPO) resin having a structure represented by formula (V):

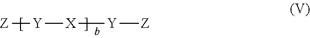

wherein b is a positive integer, X is selected from any one of formula (VI) to formula (VIII) and a combination thereof:

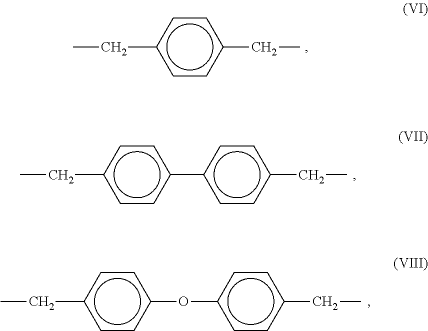

Y has a structure represented by formula (IX):

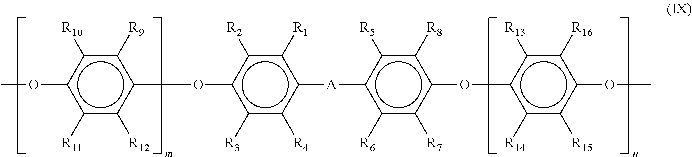

wherein m and n independently represent a positive integer of 1 to 30; R₁ to R₁₆ are independently selected from H, —CH₃ and halogen atoms; A is selected from a covalent bond, —CH₂—, —CH(CH₃)—, —C(CH₃)₂—, —O—, —S—, —SO₂ and carbonyl group, preferably selected from CH₂—, —CH(CH₃)—, —C(CH₃)₂—, —O—, —S—, —SO₂ and carbonyl group;
and Z has a structure of formula (X), (XI) or (XII) or a combination thereof, preferably has a structure of formula (X) or (XII) or a combination thereof:

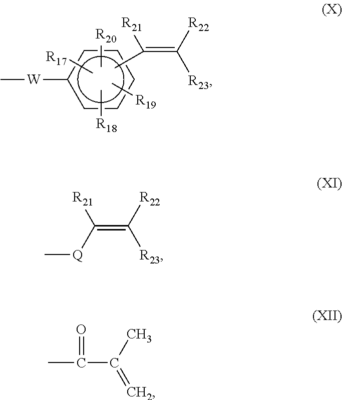

wherein R₁₇ to R₂₃ are independently selected from H, —CH₃ and halogen atoms, and Q and W are independently an aliphatic group.

Suitable poly(p-phenylene oxide) (PPO) resin are SA-90: dihydroxyl-terminated polyphenylene oxide, available from SABIC; SA-9000: methacrylate-terminated bisphenol A polyphenylene oxide resin, available from SABIC; and OPE-2st: bis(vinylbenzyl)-terminated polyphenylene oxide resin, available from Mitsubishi Gas Chemical Co., Inc.

In one embodiment, the monomer, oligomer, prepolymer, and/or polymer being polymerizable by exposure to actinic radiation or light (B1) is selected from the group consisting of difunctional epoxy acrylate oligomer, trimethylolpropane triacrylate, a diallylbisphenol A dicyanate ester (e.g. CL-100), bisallylnadic imide, 1,3-bis(citraconimidomethyl)benzene, copolymers of butadiene and styrene (e.g. having a molecular weight (Mn) of 1,000 to 1,000,000 g/mol), homopolymers of butadiene such as maleinized butadiene e.g. Ricon 130, and olefin and/or (meth)acrylate poly(p-phenylene oxide) (PPO) resin (e.g. SA-9000 or OPE).

In one embodiment, the resin composition further comprises a monomer, oligomer, prepolymer, and/or polymer being polymerizable by exposure to actinic radiation or light (B2) different to (B1).

In this connection, it is to be understood that (B2) can be any above-outlined monomer, oligomer, prepolymer, and/or polymer as defined for (B1), with the proviso that it differs in e.g. molecular weight and/or functionalities.

In one embodiment, the monomer, oligomer, prepolymer, and/or polymer being polymerizable by exposure to actinic radiation or light (B2) comprises reactive end groups selected from the group consisting of acrylates, methacrylates, olefins such as α-olefins, N-vinyls, acrylamides, methacrylamides, styrenics, epoxides, oxetanes, thiols, 1,3-dienes, vinyl halides, acrylonitriles, vinyl esters, maleimides, bisnadicimides, vinyl ethers, cyanate esters, bisbenzocyclobutenes, and mixtures thereof.

In one embodiment, the monomer, oligomer, prepolymer, and/or polymer being polymerizable by exposure to actinic radiation or light (B2) comprises reactive end groups selected from the group consisting of acrylates, methacrylates, α-olefins, epoxides, oxetanes, maleimides, cyanate esters, bisbenzocyclobutenes, and mixtures thereof, and in particular selected from the group consisting of acrylates, methacrylates, olefins, epoxides, maleimides, cyanate esters, and mixtures thereof.

In one embodiment, the monomer, oligomer, prepolymer, and/or polymer being polymerizable by exposure to actinic radiation or light (B2) is selected from the group consisting of difunctional epoxy acrylate oligomer, trimethylolpropane triacrylate, diallylbisphenol A cyanate ester, bisallylnadicimide, 1,3-bis(citraconimidomethyl)benzene, copolymers of butadiene and styrene (e.g. having a molecular weight (Mn) of 1,00 to 1,000,000 g/mol), homopolymers of butadiene such as maleinized butadiene e.g. Ricon 130, and olefin and/or (meth)acrylate poly(p-phenylene oxide) (PPO) resin (e.g. SA-9000 or OPE).

In one embodiment, (B1) and (B2) have a weight ratio of 100:1 to 1:100, preferably of 5:1 to 1:5 or of 4:1 to 1:4, or of 3:1 to 1:3, or of 2:1 to 1:2, or of 1.5:1 to 1:1.5, or of about 1:1.

In one embodiment, (B1) comprises reactive end groups selected from the group consisting olefins such as α-olefins and acrylates and (B2) comprises reactive cyanate ester end groups, preferably wherein (B1) is trimethylolpropane triacrylate and (B2) is a diallylbisphenol A dicyanate ester.

In one embodiment, the catalyst is a photo initiator, preferably selected from the group consisting of radical initiator, Lewis acid catalyst, and mixtures thereof.

As an example of the catalyst that can be used, it is preferable to use a radical initiator for the purpose of promoting self-polymerization of a radically polymerizable curable resin such as an olefin compound or a maleimide resin, or radical polymerization with other components. Examples of the radical initiators that can be used include, but are not limited to, known curing accelerators: ketone peroxides such as methyl ethyl ketone peroxide and acetylacetone peroxide; diacyl peroxides such as benzoyl peroxide; dialkyl peroxides such as dicumyl peroxide and 1,3-bis(t-butylperoxyisopropyl)-benzene; peroxyketals such as t-butylperoxybenzoate and 1,1-di-t-butylperoxycyclohexane; alkyl peresters such as α-cumylperoxyneodecanoate, t-butylperoxyneodecanoate, t-butylperoxypivalate, 1,1,3,3-tetramethylbutylperoxy-2-ethylhexanoate, t-mylperoxy-2-ethylhexanoate, t-butylperoxy-2-ethylhexanoate, t-amylperoxy-3,5,5-trimethylhexanoate, t-butylperoxy-3, 5, 5-trimethylhexanoate and t-amylperoxybenzoate; peroxycarbonates such as di-2-ethylhexylperoxydicarbonate, bis(4-t-butylcyclohexyl) peroxydicarbonate, t-butylperoxyisopropyl carbonate and 1,6-bis(t-butylperoxycarbonyloxy) hexane; organic peroxides such as t-butyl hydroperoxide, cumene hydroperoxide, t-butylperoxyoctoate, and lauroyl peroxide; and azo compounds such as azobisisobutyronitrile, 4,4′-azobis(4-cyanovaleric acid) and 2,2′-azobis(2,4-dimethylvaleronitrile). The ketone peroxides, diacyl peroxides, hydroperoxides, dialkyl peroxides, peroxyketals, alkyl peresters, percarbonates, and the like are preferred, and the dialkyl peroxides are more preferred. The addition amount of the radical initiator is preferably 0.01 to 5 parts by mass, and particularly preferably 0.01 to 3 parts by mass, based on 100 parts by mass of the resin composition. When the amount of the radical initiator used is large, the molecular weight does not sufficiently extend during the polymerization reaction.

Suitable radical initiators include but are not limited to dialkyl peroxides, diacyl peroxides, and azo compounds. Particularly suitable radical initiators include dicumyl peroxide and 2,5-Dimethyl-2,5-di-(tert-butylperoxy)hexyne-3 (Trigonox 145-E85). Radical initiators may be added at any level suitable to effect sufficient polymerization, ranging from ppm levels to 5 wt % depending on initiator used. Radical initiators may be combined with other radical initiators or other classes of suitable catalysts as desired to affect the polymerization.

In one embodiment, the radical initiator is selected from the group consisting of dialkyl peroxide, diacyl peroxide, azo compound, and mixtures thereof.

In one embodiment, the Lewis acid catalysts is selected from the group consisting of a cationic thermal acid generator, a cationic photo-acid generator, and mixtures thereof.

Suitable Lewis acid catalysts include but are not limited to cationic thermal acid generators, cationic photo-acid generators, or other Lewis acid catalysts, including but not limited to transition metal complexes, boron compounds, aluminum compounds, titanium compounds, or tin compounds.

Other suitable Lewis acid catalysts include boron compounds, aluminum compounds, titanium compounds, tin compounds and compounds of transition metals known in the art. Particularly suitable Lewis acid initiators include bis(4-dodecylphenyl)iodonium hexafluoroantimonate such as SpeedCure 937 available from Arkema, bis-(4-t-butylphenyl)-iodonium hexafluorophosphate such as SpeedCure 938 available from Arkema, 4-isopropyl-4′-methyldiphenyliodonium tetrakis(pentafluorophenyl)borate such as SpeedCure 939 available from Arkema, and (sulfanediy Idibenzene-4,1-diyl)bis(diphenyl sulfonium) bis(hexafluoroantimonate) such as 5 SpeedCure 976s available from Arkema and stannous octoate such as Reaxis C129 available from Reaxis. Lewis acid initiators may be added at any level suitable to effect sufficient polymerization, ranging from ppm levels to 5 wt %, depending on the initiator used. Lewis acid initiators may be combined with other Lewis acid initiators or other classes of suitable catalysts as desired to affect the polymerization.

Cationic thermal acid generators and cationic photo-acid generators produce strong acids upon activation at elevated temperature or upon absorption of specific energy wavelengths. Suitable cationic thermal acid generators and cationic photo-acid generators include onium salts such as iodonium and sulfonium salts. Suitable catalysts include but are not limited to diaryliodonium compounds or triarylsulfonium compounds paired with anions such as BF4-, B(C6F5)4-, PF6-, AsF6-, SbF6- and variations thereof.

In one embodiment, the catalyst is selected from the group consisting of camphor quinone; benzophenone, benzophenone derivatives, such as 2,4,6-trimethylbenzophenone, 2-methylbenzophenone, 3-methylbenzo-phenone, 4-methylbenzophenone, 2-methoxycarbonylbenzophenone 4,4′-bis(chloromethyl)-benzophenone, 4-chlorobenzophenone, 4-phenylbenzophenone, 3,3′-dimethyl-4-methoxy-benzophenone, [4-(4-methylphenylthio)phenyl]-phenylmethanone, methyl-2-benzoyl-benzoate, 3-methyl-4′-phenylbenzophenone, 2,4,6-trimethyl-4′-phenylbenzophenone, 4,4′-bis(dimethylamino)benzophenone, 4,4′-bis(diethylamino)benzophenone; thioxanthones, thioxanthone derivatives, polymeric thio-xanthones as for example OMNIPOL TX; ketal compounds, as for example benzyldimethyl-ketal (IRGACURE® 651); acetophenone, acetophenone derivatives, for example α-hydroxy-cycloalkyl phenyl ketones or α-hydroxyalkyl phenyl ketones, such as for example 2-hydroxy-2-methyl-1-phenyl-propanone (DAROCUR® 1173), 1-hydroxy-cyclohexyl-phenyl-ketone (IRGACURE® 184), 1-(4-dodecylbenzoyl)-1-hydroxy-1-methyl-ethane, 1-(4-isopropylbenzoyl)-1-hydroxy-1-methyl-ethane, 1-[4-(2-hydroxyethoxy)-phenyl]-2-hydroxy-2-methyl-1-propan-1-one (IRGACURE® 2959); 2-hydroxy-1-{4-[4-(2-hydroxy-2-methyl-propionyl)-benzyl]-phenyl}-2-methyl-propan-1-one (IRGACURE® 127); 2-hydroxy-1-{4-[4-(2-hydroxy-2-methyl-propionyl)-phenoxy]-phenyl}-2-methyl-propan-1-one; dialkoxyacetophenones, α-hydroxy- or α-am-inoacetophenones, e.g., (4-methylthiobenzoyl)-1-methyl-1-morpholinoethane (IRGACURE® 907), (4-morpholinobenzoyl)-1-benzyl-1-dimethylaminopropane (IRGACURE® 369), (4-morpholinobenzoyl)-1-(4-methylbenzyl)-1-dimethylaminopropane (IRGACURE® 379), (4-(2-hydroxyethyl)aminobenzoyl)-1-benzyl-1-dimethylaminopropane), (3,4-dimethoxybenzoyl)-1-benzyl-1-dimethyl aminopropane; 4-aroyl-1,3-dioxolanes, benzoin alkyl ethers and benzyl ketals, e.g. dimethyl benzyl ketal, phenylglyoxalic esters and derivatives thereof, e.g., methyl α-oxo benzeneacetate, oxo-phenyl-acetic acid 2-(2-hydroxy-ethoxy)-ethyl ester, dimeric phenylglyoxalic esters, e.g. oxo-phenyl-acetic acid 1-methyl-2-[2-(2-oxo-2-phenyl-acetoxy)-propoxy]-ethyl ester (IRGACURE® 754); ketosulfones, e.g. ESACURE KIP 1001 M®; oxime-esters, e.g., 1,2-octanedione 1-[4-(phenylthio)phenyl]-2-(0-benzoyloxime) (IRGACURE® OXEOI), ethanone 1-[9-ethyl-6-(2-methylbenzoyl)-9H-carbazol-3-yl]-1-(O-acetyloxime) (IRGACURE® OXE02), 9H-thioxanthene-2-carboxaldehyde 9-oxo-2-(0-acetyloxime), peresters, benzophenone tetracarboxylic peresters, monoacyl phosphine oxides, e.g. (2,4,6-trimethylbenzoyl)diphenylphosphine oxide (DAROCUR® TPO), ethyl(2,4,6 trimethylbenzoyl phenyl)phosphinic acid ester; bisacyl-phosphine oxides, e.g., bis(2,6-dimethoxy-benzoyl)-(2,4,4-trimethyl-pentyl)phosphine oxide, bis(2,4,6-trimethylbenzoyl)-phenylphosphine oxide (IRGACURE®819), bis(2,4,6-trimethyl-benzoyl)-2,4-dipentoxyphenylphosphine oxide, trisacylphosphine oxides, halomethyltriazines, e.g., 2-[2-(4-methoxy-phenyl)-vinyl]-4,6-bis-trichloromethyl-[1,3,5]triazine, 2-(4-methoxy-phenyl)-4,6-bis-trichloromethyl-[1,3,5]triazine, 2-(3,4-dimethoxy-phenyl)-4,6-bis-trichlorome-thyl-[1,3,5]triazine, 2-methyl-4,6-bis-trichloromethyl-[1,3,5]triazine, hexaarylbisimidazole/co-initiators systems, e.g., ortho-chlorohexaphenyl-bisimidazole combined with 2-mercapto-benzthiazole, ferrocenium compounds, titanocenes, e.g., bis(cyclopentadienyl)-bis(2,6-difluoro-3-pyrryl-phenyl)titanium (IRGACURE® 784), bis(2,4,6-trimethylbenzoyl)-phenylphosphineoxide, bis-(4-dodecylphenyl)iodonium hexafluroantimonate in glycidyl ether, (sulfanediyldibenzene-4,1-diyl)bis(diphenylsulfonium) bis(hexafluoroantimonate) in digycidyl ether, ethyl phenyl(2,4,6-trimethylbenzoyl)phosphinate, low viscosity monofunctional oxetane, 1,4-bis[(3-ethyl-3-oxetanylmethoxy)methyl]benzene, 7-oxabicyclo[4.1.0]hept-3-ylmethyl 7-oxabicyclo[4.1.0]heptane-3-carboxylate, and mixtures thereof.

In one embodiment, the resin composition further comprises a sensitizer such as isopropyl-9H-thioxanthen-9-on (including mixtures of 2- and 4-isomer of Isopropyl-9H-thioxanthen-9-on).

In one embodiment, the resin composition comprise at least 25 wt % such as at least 30 wt %, or at least 35 wt %, or at least 40 wt %, or at least 45 wt %, or at least 50 wt %, or at least 60 wt %, or at least 65 wt %, or at least 70 wt %, or at least 75 wt %, or at least 80 wt %, or at least 85 wt %, or at least 90 wt %, or at least 95 wt %, of the hydrocarbon resin composition, based on the total weight of the resin composition. In one embodiment, the resin composition comprises up to 99.9 wt % such as up to 98 wt %, or up to 95 wt %, or up to 90 wt %, or up to 85 wt %, or up to 80 wt %, or up to 75 wt %, or up to 70 wt %, or up to 65 wt %, or up to 60 wt %, or up to 55 wt %, or up to 50 wt %, of the hydrocarbon resin composition, based on the total weight of the resin composition.

In one embodiment, the resin composition comprises 30 to 99.9 wt % such as 35 to 80 wt %, or 30 to 50 wt %, or 35 to 75 wt %, or 45 to 75 wt %, or 50 to 80 wt %, or 50 to 84 wt %, of the hydrocarbon resin composition, based on the total weight of the resin composition.

In another embodiment, the resin composition comprises 50 to 98 wt %, or 55 to 98 wt %, or 60 to 90 wt %, of the hydrocarbon resin composition, based on the total weight of the resin composition.

In one embodiment, the resin composition comprises 7.5 to 69.99 wt % such as 50 to 69.99 wt %, or 19 to 64 wt %, or 10 to 40 wt %, or 19 to 59 wt %, or 20 to 40 wt %, or 7 to 30 wt %, or 7.5 to 25 wt %, of (B1), based on the total weight of the resin composition.

In one embodiment, the resin composition comprises 7.5 to 25 wt % of (B2), based on the total weight of the resin composition.

In one embodiment, the resin composition comprises 0.01 to 15 wt % such as 1 to 6 wt %, or 1 to 7 wt %, or 1 to 8 wt %, of the catalyst (C), based on the total weight of the resin composition.

In one embodiment, the composition comprises
30 to 92 wt % of the hydrocarbon resin composition,
7.5 to 69.5 wt % of (B1), and
0.5 to 8 wt % of the catalyst (C),
each wt % based on the total weight of the resin composition.

In one embodiment, the resin composition further comprises a solvent (S1), preferably an organic solvent, more preferably selected from the group consisting of acetone, butanon, tetrahydrofuran, 2-methyl tetrahydrofuran, ethyl acetate, butyl acetate, toluene, xylene, dimethylformamide, N-methyl-2-pyrrolidone, dimethyl toluene, methyl ethyl ketone, methyl isobutyl ketone, dimethylacetamide, N-methylpyrrolidone, and mixtures thereof, and in particular selected from the group consisting of acetone, butanon, and mixtures thereof.

In one embodiment, the resin composition comprises 20 to 45 wt %, preferably 30 to 40 wt %, of the solvent (S1), based on the total weight of the resin composition.

In one embodiment, the resin composition comprises
25 to 74 wt %, preferably 33 to 66 wt %, of the hydrocarbon resin composition,
25 to 74 wt %, preferably 33 to 66 wt %, of (B1), and
1 to 6 wt %, preferably 1 to 3 wt %, of the catalyst (C),
each wt % based on the total weight of the resin composition.

In one embodiment, the resin composition comprises
30 to 50 wt %, preferably 32 to 45 wt %, of the hydrocarbon resin composition,
10 to 40 wt %, preferably 20 to 30 wt %, of (B1),
1 to 7 wt %, preferably 2 to 6 wt %, of the catalyst (C), and
20 to 45 wt %, preferably 30 to 40 wt %, of the solvent (S1),
each wt % based on the total weight of the resin composition.

In one embodiment, the resin composition comprises
35 to 75 wt %, preferably 40 to 54 wt %, of the hydrocarbon resin composition,
19 to 59 wt %, preferably 25 to 35 wt %, of (B1),
1 to 8 wt %, preferably 3 to 7 wt %, of the catalyst (C), and
5 to 25 wt %, preferably 10 to 20 wt %, of the solvent (S1),
each wt % based on the total weight of the resin composition.

In one embodiment, the resin composition comprises
45 to 75 wt %, preferably 55 to 65 wt %, of the hydrocarbon resin composition,
20 to 40 wt %, preferably 25 to 35 wt %, of (B1),
1 to 8 wt %, preferably 2 to 6 wt %, of the catalyst (C), and
1 to 15 wt %, preferably 4 to 10 wt %, of the solvent (S1),
each wt % based on the total weight of the resin composition.

In one embodiment, the resin composition comprises
50 to 80 wt %, preferably 60 to 70 wt %, of the hydrocarbon resin composition,
7 to 30 wt %, preferably 8 to 20 wt %, of (B1),
1 to 6 wt %, preferably 3 to 6 wt %, of the catalyst (C), and
7 to 30 wt %, preferably 8 to 20 wt %, of the solvent (S1),
each wt % based on the total weight of the resin composition.

In one embodiment, the resin composition comprises
50 to 84 wt %, preferably 60 to 82 wt %, of the hydrocarbon resin composition,
7.5 to 25 wt %, preferably 8 to 20 wt %, of (B1),
7.5 to 25 wt %, preferably 8 to 20 wt %, of (B2), and
1 to 8 wt %, preferably 2 to 6 wt %, of the catalyst (C),
each wt % based on the total weight of the resin composition.

In one embodiment, the hydrocarbon resin having a structure as defined by formula (A1) and the hydrocarbon resin having a structure as defined by formula (A2) are present in the hydrocarbon resin composition in a weight ratio of 100:1 to 1:100, preferably of 50:1 to 1:50, more preferably of 10:1 to 1:10 such as of 4:1 to 1:4 or of 3:1 to 1:3, or of 2:1 to 1:2, or of 1.5:1 to 1:1.5, or of about 1.2:1 to 1:1.2.

In one embodiment, the hydrocarbon resin composition and the monomer, oligomer, prepolymer, and/or polymer being polymerizable by exposure to actinic radiation or light (B1) are present in the resin composition in a weight ratio of about 99:1 to about 10:90, preferably of about 95:5 to about 20:80, more preferably of about 92:8 to about 40:60, and in particular of about 90:10 to about 60:30.

In one embodiment, the hydrocarbon resin composition and the sum of the monomer, oligomer, prepolymer, and/or polymer being polymerizable by exposure to actinic radiation or light (B1) and monomer, oligomer, prepolymer, and/or polymer being polymerizable by exposure to actinic radiation or light (B2) are present in the resin composition in a weight ratio of about 99:1 to about 10:90, preferably of about 95:5 to about 20:80, more preferably of about 92:8 to about 40:60, and in particular of about 90:10 to about 60:30.

As aforementioned, the present invention relates in a second aspect to a process of curing the resin composition according to the first aspect comprising the step of heating and/or irradiating said resin composition.

Particular embodiments (e.g. regarding the ingredients, amounts, and moieties) are already above-outlined in connection with the inventive resin composition and shall hold for the process of curing, as well. In the following, particular embodiments of the process of curing are described in further detail. It is to be understood that each embodiment is relevant on its own as well as in combination with other embodiments.

In one embodiment, the process is directed to a process of manufacturing a cured resin (CR1), the process comprising curing the resin composition according to the first aspect comprising the step of heating and/or irradiating said resin composition.

In one embodiment, the cured resin (CR1) is at 25 °C not soluble in a mixture of water and acetone. In this connection, it is to be understood that a solid film can be obtained, which is at 25 °C not soluble in a mixture of water and acetone. Said solid film can undergo further curing, e.g. thermally or via irradiation.

In one embodiment, the resin composition is irradiated with UV-Vis light, preferably having a wavelength of 10 to 500 nm, more preferably of 100 to 450 nm, and in particular of 280 to 400 nm. The resin composition is suitably irradiated for 0.1 to 3 hours, preferably for 0.1 to 2.5 hours, more preferably for 0.2 to 2 hours, still more preferably for 0.4 to 1.2 hours.

In one embodiment, the resin composition is heated to a temperature of room temperature to less than 80 °C, preferably of 30 to 80 °C, more preferably of 40 to 75 °C, still more preferably of 50 to 60 °C for 0.1 to 3 hours, preferably for 0.1 to 2.5 hours, more preferably for 0.2 to 2 hours, still more preferably for 0.3 to 1 hours.

In one embodiment, the process is directed to a process of manufacturing a cured resin (CR2), the process comprising curing the cured resin (CR1) by heating and/or microwave irradiating.

In one embodiment, the cured resin (CR1) is heated to a temperature of 80 to 400 °C, preferably of 100 to 300 °C, more preferably of 120 to 250 °C, for 0.5 to 10 hours, preferably for 1 to 5 hours, more preferably for 2 to 4 hours.

In one embodiment, the process provides a cured resin (CR2) having a Tg (determined by Tg onset via TMA measurement) of more than 150 °C, preferably of more than 150 to 400 °C, more preferably of 160 to 300 °C, and in particular of 180 to 260 °C. In general, Tg may also be determined by tan 6 measurement via DMA.

The T_{g} glass transition temperature can be measured by any known in the art method such as Thermal Mechanical Analysis (TMA). A suitable machine used is a Mettler Toledo instrument TMA SDTA840. In one embodiment, the resin composition according to the first aspect is transferred in a mould and optionally pressed. In this connection, the press can be adjusted to about 0.1 to 1.3 tons such as about 0.4 to about 1.0 tons or about 0.7 tons.

In one embodiment, the mould is preheated such as to a temperature of about 50 to about 250 °C, preferably about 70 to about 200 °C, more preferably about 80 to about 150 °C.

In one embodiment, the resin composition in the mould is cured thermally, preferably by heating to about 70 to about 400 °C, preferably to about 80 to about 300 °C, more preferably to about 90 to about 250 °C.

In one embodiment, the resin composition in the mould is cured under ramped heating. Suitably, the ramped heating comprises at least two such as three heating ramps. Suitable ramped heating includes starting at about 50 to about 130 °C, preferably about 80 to about 120 °C (keeping said temperature for e.g. about 0.5 to about 4 hours, preferably for about 1 to 3 hours); going to about 70 to about 180 °C, preferably about 110 to about 130 °C, with about 0.5 to about 2 °C/min, preferably about 0.8 to about 1.2 °C/min, keeping the temperature for about 0.5 to about 4 hours, preferably for about 1 to about 3 hours; followed by going to about 115 to about 210 °C, preferably about 130 to about 170 °C, with about 0.5 to about 2 °C/min, preferably about 0.8 to about 1.2 °C/min, keeping the temperature for about 0.5 to about 4 hours, preferably for about 1 to about 3 hours; followed by going to about 150 to about 350 °C, preferably about 200 to about 260 °C, with about 0.5 to about 2 °C/min, preferably about 0.8 to about 1.2 °C/min, keeping the temperature for about 0.5 to about 4 hours, preferably for about 1 to about 3 hours; followed by cooling to e.g. room temperature.

As aforementioned, the present invention relates in a third aspect to a cured resin obtainable by the process according to the second aspect.

Particular embodiments (e.g. regarding the ingredients, amounts, moieties, and curing conditions) are already above-outlined in connection with the inventive resin composition and process and shall hold for the cured resin, as well. In the following, particular embodiments of the cured resin are described in further detail. It is to be understood that each embodiment is relevant on its own as well as in combination with other embodiments.

In one embodiment, the present invention relates to a cured resin obtained by the process according to the second aspect.

In one embodiment, the cured resin is a cured resin (CR1).

In one embodiment, the cured resin (CR1) is at 25 °C not soluble in a mixture of water and acetone.

In one embodiment, the cured resin is a cured resin (CR2).

In one embodiment, the cured resin (CR2) has a Tg (determined by Tg onset via TMA measurement) of more than 150 °C, preferably of more than 150 to 400 °C, more preferably of 160 to 300 °C, and in particular of 180 to 260 °C.

As aforementioned, the invention relates in a fourth aspect to a 3D printing resin composition or to a pre-structuring resin composition comprising the resin composition according to the first aspect (including all embodiments).

Particular embodiments (e.g. regarding the ingredients, amounts, moieties, and curing conditions) are already above-outlined in connection with the inventive resin composition and shall hold for the compositions, as well.

The 3D printing resin composition or the pre-structuring resin composition may comprise any suitable additive. The skilled person will be aware of typical additives.

In one embodiment, the 3D printing resin composition or the pre-structuring resin composition further comprises additional components selected from the group consisting of (internal) mold release agents, fillers, reactive diluents, and mixtures thereof.

Internal mold release agents are preferably present in amounts of 0 to 5 wt %, based on the total amount of components hydrocarbon resin composition, (B1), and (C). Examples of suitable internal mold release agents to be added to the resin composition (e.g. being a liquid mixture) are Axel XP I PHPUL-1 (a proprietary synergistic blend of organic fatty acids, esters and amine neutralizing agent) and Axel MoldWiz® INT-1850HT (a proprietary synergistic blend of organic fatty acids, esters and alkanes and alkanols, supplier: Axel Plastics Research Laboratories, Inc., Woodside NY, USA). Other mold release agents are usually rubbed on a mold surface. Examples of those mold release agents are Frekote® 700-NC (a mixture of hydrotreated heavy naphtha (60-100%), dibutyl ether (10-30%), naphtha (petroleum) light alkylate (1-5%), octane (1-5%) and proprietary resin (1-5%); supplier: Henkel AG & Co. KGaA, Düsseldorf, Germany) or Chemlease R&B EZ (a mixture of hydrocarbon C7-C9 isoalkanes (50-700%), alkanes C9-12-iso (10-20%), low boiling point naphtha (5-10%), hydrocarbon isoalkanes (1-2.5%) supplier: Chem-trend Maisach-Gernlinden Germany). The expression “liquid mixture” means a mixture that is liquid at ambient temperature (typically about 25 °C and/or by Brookfield viscosimeter) and has a viscosity of preferably less than 10,000 mPa×s at ambient temperature and preferably less than 2,000 mPa×s, more preferably less than 1,000 mPa×s, and most preferably no more than about 500 mPa×s at a temperature of 80 °C or less.

Fillers are preferably present in amounts of 0 to 40 wt %, based on the total amount of components hydrocarbon resin composition, (B1), and (C). They may be in particle, powder, sphere, chip and/or strand form in sized from nano scale to millimeters. Suitable fillers may be organic, such as thermoplastics and elastomers, or inorganic, such as glass microspheres, graphite, or silica; and mineral powders, preferably CaCO₃, coated CaCO₃, kaolin clay, SiO₂ (e.g. sand), talc, graphite, corundum (α-Al₂O₃), wollastonite, SiC, glass microspheres, mica, calcium silicate (Ca₂O₄Si), MgO, anhydrous calcium sulfate (CaSO₄ or anhydrite), ceramic hollow microspheres, fused mullite (Al₂O₃—SiO₂), boron nitride (BN), vermiculite, or basalt; and mixtures thereof. Preferably, the filler is sand.

Reactive diluents are preferably present in amounts of 0 to 20 wt %, based on the amount of component (B1). Examples of suitable reactive diluents are liquid mono-, di- or trifunctional epoxy compounds derived from aliphatic or cycloaliphatic alcohols or phenols, such as diglycidyl ethers of glycols, in particular 1,ω alkanediols having 4 to 12 carbon atoms, for example 1,4-(diglycidyloxy)butane or 1,12-(diglycidyloxy)-dodecane, or the diglycidyl ether of neopentyl glycol, glycidyl ethers of linear or branched primary alcohols having 8 to 16 carbon atoms, for example 2 ethylhexyl glycidyl ether or C8-C16 alkyl glycidyl ether, or the diglycidyl ether of 1,4-cyclohexanedimethanol.

As aforementioned, the present invention relates in a fifth aspect to a process for manufacturing a pre-structured object, the process comprising the steps of
a) providing a resin composition (RC) comprising
a.1) a hydrocarbon resin composition (HRC) comprising a hydrocarbon resin derived from a structure as defined by formula

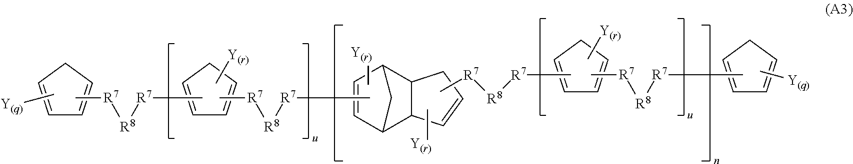

wherein
R⁷ is independently a methylene group (CH₂) or a methylene group substituted with one or more —CH₃ or halogen functionalities;
R⁸ is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety;
q is an integer of 1 to 5;
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
a.2) optionally a monomer, oligomer, prepolymer, and/or polymer being polymerizable by exposure to actinic radiation or light (B1); and
a.3) a photo initiator;
b) forming a resin composition layer having a thickness of 5 to 800 μm from the resin composition (RC);
c) irradiating the resin composition layer by means of a photomask providing a layer (L1), which at 25 °C is not soluble in a mixture of water and acetone;
d) washing the layer (L1) with a solvent (S2); and
e) curing the layer (L1) providing a layer (L2) having a Tg (determined by Tg onset via TMA measurement) of more than 150 °C.

It is to be understood that washing step d) removes non irradiated material and that cured layer (L1) is not affected by this step.

Particular embodiments (e.g. regarding the ingredients, amounts, moieties, and curing conditions) are already above-outlined in connection with the inventive resin composition and curing process and shall hold for the pre-structuring process, as well. In the following, particular embodiments of the pre-structuring process are described in further detail. It is to be understood that each embodiment is relevant on its own as well as in combination with other embodiments.

In one embodiment, the forming step b) provides a resin composition layer having a thickness of 20 to 600 μm, preferably of 50 to 500 μm, more preferably of 80 to 400 μm, still more preferably of 100 to 350 μm, and in particular of 120 to 250 μm.

In one embodiment, the forming step b) is conducted by spreading out the resin composition (RC), preferably on a substrate.

In one embodiment, the photomask comprises UV-impermeable and UV-permeable parts.

In one embodiment, the irradiating step c) is conducted with UV-Vis light, preferably having a wavelength of 10 to 500 nm, more preferably of 100 to 450 nm, and in particular of 280 to 400 nm. The resin composition layer is suitably irradiated for 0.1 to 3 hours, preferably for 0.1 to 2.5 hours, more preferably for 0.2 to 2 hours, still more preferably for 0.4 to 1.2 hours.

In one embodiment, the irradiating step c) is conducted for 1 second to 1 hour, preferably for 5 seconds to 30 minutes, and in particular for 15 seconds to 15 minutes.

In one embodiment, the irradiating step c) is conducted at a temperature of about 15 to about 40 °C such as of about 20 to about 30 °C. In one embodiment, the irradiating step c) is conducted at room temperature (such as about 25 °C).

In one embodiment, the layer (L1) has a Tg (determined by Tg onset via TMA measurement) of −30 to 150 °C such as of −25 °C to 140 °C, or of 10 to 130 °C, or of 40 to 120 °C, or of 80 to 100 °C.

In one embodiment, the layer (L2) has a Tg (determined by Tg onset via TMA measurement) of more than 150 to 400 °C, preferably of 160 to 300 °C, and in particular of 180 to 260 °C.

In one embodiment, layer (L2) has a dissipation (Df) value of about 0.0001 to about 0.004.

In one embodiment, layer (L2) has a dielectric (Dk) value of about 1.5 to about 3 at 1-50 GHz.

In one embodiment, the solvent (S2) is selected from the group consisting of cyclohexane, ethyl acetate, butyl acetate, toluene, methyl ethyl ketone, xylenes, N-methyl pyrrolidone, dimethylformamide, dichloromethane, acetonitrile, acetone, dimethyl sulfoxide, tetrahydrofuran, water, and mixtures thereof, preferably selected from the group consisting of water, acetone, and mixtures thereof.

In one embodiment, the layer (L1) is at 25 °C and ambient pressure not soluble in a solvent selected from the group consisting of cyclohexane, ethyl acetate, butyl acetate, toluene, methyl ethyl ketone, xylenes, N-methyl pyrrolidone, dimethylformamide, dichloromethane, acetonitrile, acetone, dimethyl sulfoxide, tetrahydrofuran, water, and mixtures thereof.

In one embodiment, curing the layer (L1) in step e) is conducted by heating and/or microwave irradiating.

In one embodiment, curing the layer (L1) in step e) is conducted thermally, preferably by heating the layer (L1) to 80 to 400 °C, preferably to 100 to 300 °C, more preferably to 120 to 250 °C.

In one embodiment, the layer (L1) in step e) is cured for 0.5 to 10 hours, preferably for 1 to 5 hours, more preferably for 2 to 4 hours.

In one embodiment, the layer (L1) in step e) is cured under ramped heating. Suitable ramped heating includes starting at 60 to 95 °C, preferably 75 to 85 °C, going to 100 to 140 °C, preferably 110 to 130 °C, with 0.5 to 2 °C/min, preferably 0.8 to 1.2 °C/min, keeping the temperature for 2 to 4 hours, preferably 2.5 to 3.5 hours, followed by going from 100 to 140 °C, preferably from 110 to 130 °C, to 190 to 250 °C, preferably to 210 to 230 °C, with 0.5 to 2 °C/min, preferably 0.8 to 1.2 °C/min, keeping the temperature for 2 to 4 hours, preferably 2.5 to 3.5 hours.

In one embodiment, the substrate comprises fillers and/or fibers.

Fillers may be in particle, powder, sphere, chip and/or strand form in sized from nano scale to millimeters. Suitable fillers may be organic, such as thermoplastics and elastomers, or inorganic, such as glass microspheres, graphite, or silica; and mineral powders, preferably CaCO₃, coated CaCO₃, kaolin clay, SiO₂ (e.g. sand), talc, graphite, corundum (α-Al₂O₃), wollastonite, SiC, glass microspheres, mica, calcium silicate (Ca₂O₄Si), MgO, anhydrous calcium sulfate (CaSO₄ or anhydrite), ceramic hollow microspheres, fused mullite (Al₂O₃—SiO₂), boron nitride (BN), vermiculite, or basalt; and mixtures thereof. Preferably, the filler is sand.

Fibers include carbon fibers, glass fibers (e.g. E glass fibres or S glass fibres), quartz fibers, boron fibers, ceramic fibers, aramid fibers (including KEVLAR®), polyester fibers, polyethylene fibers, or natural fibers (e.g. flax, hemp, jute or sisal). The fibers may be strands, yarns, rovings, unidirectional fabrics, 0/90° fabrics, woven fabrics (multi-layered or single layered), hybrid fabrics, multiaxial fabrics, chopped strand mats, tissues, braids, and combinations thereof.

The fibers may be pre-shaped fibers. The fibers may be chopped or continuous, random or oriented, woven or non-woven, knitted or non-knitted or braided according to the requirements of any of various different portions of the desired structure of the substrate.

In one embodiment, the substrate comprises a composite material, preferably composed of woven fiberglass cloth with an epoxy, Cyanat ester, Bismalimide-Triazin (BT)-resin and/or polyphenylene ether (PPO) and bismaleimide (BMI) resin binder that is flame resistant.

In one embodiment, the substrate comprises flame retardants.

Suitable flame retardants may be aluminium trihydroxide (ATH), phosphorus-containing compounds and compounds as defined by formula (F),

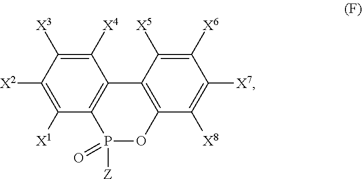

wherein
X¹ to X⁸ are independently hydrogen, alkyl, cycloalkyl, aryl, or aralkyl, and
Z is a group represented by the general formula (F1) or by the general formula (F2)

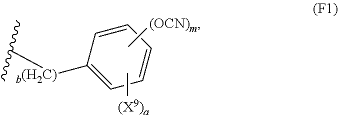

wherein
X⁹ is independently hydrogen, alkyl, cycloalkyl, aryl, or aralkyl, and
a is an integer of 1 to 4, b is 0 or an integer of 1 to 4, and m is an integer of 1 to 4, or a group;

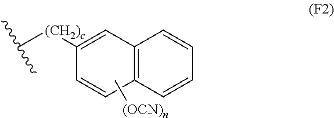

wherein
c is 0 or an integer of 1 to 4, and n is an integer of 1 to 3.

The phosphorus-containing compound may be a reactive compound or an addition-type compound.

Specific examples of the phosphorus-containing compound include: phosphoric acid esters such as trimethyl phosphate, triethyl phosphate, tricresyl phosphate, trixylylenyl phosphate, cresyl diphenyl phosphate, cresy 1-2, 6-dixylylenyl phosphate, 1,3-phenylene bis(dixylylenyl phosphate), 1,4-phenylene bis(dixylylenyl phosphate), and 4,4′-biphenyl (dixylylenyl phosphate); phosphanes such as 9,10-dihydro-9-oxa-10-phosphaphenanthrene-10-oxide and 10-(2,5-dihydroxyphenyl)-10H-9-oxa-10-phosphaphenanthrene-10-oxide; phosphorus-containing epoxy compounds obtained by allowing an epoxy resin to react with active hydrogens of the phosphanes; and red phosphorus. The phosphoric acid esters, the phosphanes, and the phosphorus-containing epoxy compounds are preferred, and 1,3-phenylenebis(dixylylenyl phosphate), 1,4-phenylene bis(dixylylenyl phosphate), 4,4′-biphenyl (dixylylenyl phosphate), or the phosphorus-containing epoxy compounds are particularly preferred. The content of the phosphorus-containing compound (phosphorus-containing compound)/(total epoxy resin) is preferably within a range of 0.1 to 0.6 (weight ratio).

Suitable phosphorus-containing compound are depicted in the following:

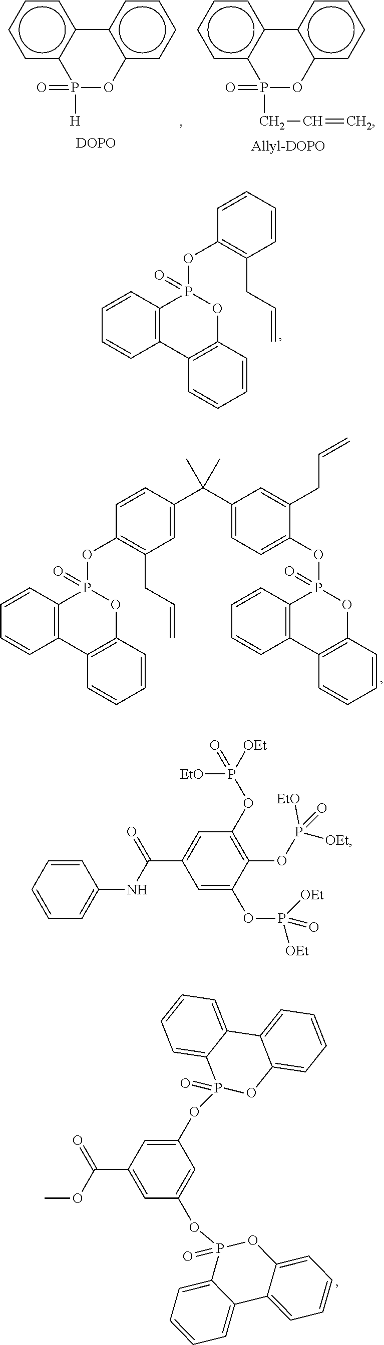

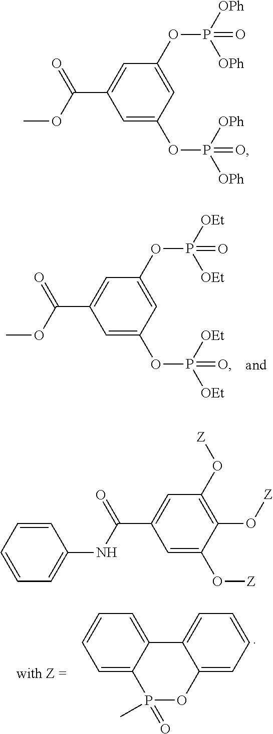

In one embodiment, the substrate or the composite material is at least partly covered by copper.

In one embodiment, the process comprises a further step wherein the layer (L1) is additionally structured, preferably by means of a laser, etching and/or a pre-structured element.

In one embodiment, a pre-structured element is pressed onto the layer (L1).

In one embodiment, the process comprises a further step wherein the layer (L2) is additionally structured, preferably by means of a laser and/or etching.

In one embodiment, the hydrocarbon resin composition (HRC) corresponds to the hydrocarbon resin composition according to the first aspect (including all embodiments).

In one embodiment, the polymer, prepolymer, or oligomer derived from a hydrocarbon resin having a structure defined by formula (A3) is present in the hydrocarbon resin composition (HRC).

In one embodiment,
R¹, R³, R⁵, and R⁷ are a methylene group (CH₂) and/or
R⁴ and R⁸ are independently a bond, a substituted or unsubstituted C6 aromatic group (e.g. phenylene or tetrafluorophenylene), or a substituted or unsubstituted C10 aromatic group (e.g. bivalent naphthol), or a substituted or unsubstituted C12 aromatic group (e.g. substituted or unsubstituted phenylene-phenylene).

In one embodiment, R² is a bond or a C1-C10 alkylene, preferably a bond or a C1-C5 alkylene, more preferably a bond or a C1-C2 alkylene, and in particular a bond.

In one embodiment, R⁶ is a substituted or unsubstituted C4-C18 aromatic group or a C4-C16 saturated or unsaturated cyclic group, preferably a substituted or unsubstituted C4-C16 aromatic group or a C4-C10 saturated or unsaturated cyclic group, more preferably a substituted or unsubstituted C6 aromatic group, a substituted or unsubstituted C10 aromatic group, a substituted or unsubstituted C12 aromatic group, a substituted or unsubstituted C13 aromatic group, a substituted or unsubstituted C14 aromatic group, a C5 saturated cyclic group, or a C6 saturated cyclic group, and in particular a substituted or unsubstituted C6 aromatic group, a substituted C10 aromatic group, or a C12 aromatic group.

In one embodiment, the hydrocarbon resin composition (HRC) comprises
a.1) a hydrocarbon resin having a structure as defined by formula (A1)

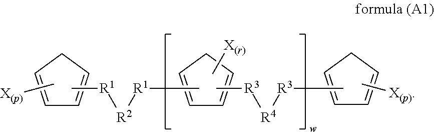

In one embodiment, the hydrocarbon resin composition (HCR) comprises
a.1) a hydrocarbon resin having a structure as defined by formula (A1-1)

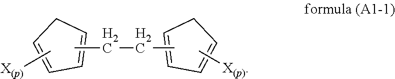

In one embodiment, the hydrocarbon resin composition (HRC) comprises
a.2) a hydrocarbon resin having a structure as defined by formula (A2)

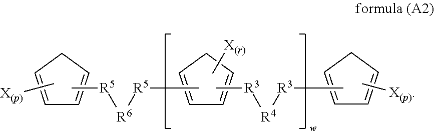

In one embodiment, the hydrocarbon resin composition (HRC) comprises (A2) (as defined in more detail above), wherein R⁶ is a substituted C6 aromatic group or a substituted or unsubstituted C12 aromatic group, preferably wherein R⁵ is a methylene group (CH₂), more preferably wherein the hydrocarbon resin composition (HRC) comprises
a.2) a hydrocarbon resin having a structure as defined by formula (A2-2)

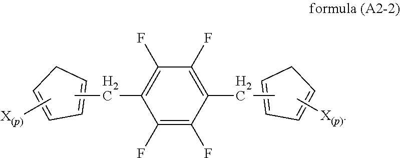

and/or
a hydrocarbon resin having a structure as defined by formula (A2-3)

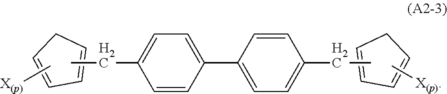

In one embodiment, the hydrocarbon resin composition (HCR) comprises
a.2) a hydrocarbon resin having a structure as defined by formula (A2-1)

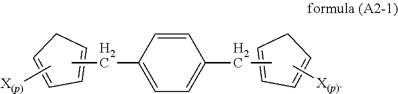

In one embodiment, the hydrocarbon resin composition (HCR) comprises
a.2) a hydrocarbon resin having a structure as defined by formula (A2-2)

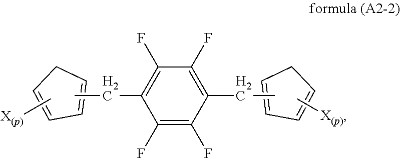

In one embodiment, the hydrocarbon resin composition (HCR) comprises
a.2) a hydrocarbon resin having a structure as defined by formula (A2-3)

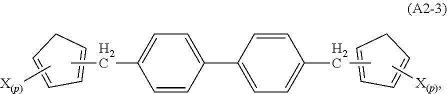

In one embodiment, the hydrocarbon resin composition (HRC) comprises
a.3) a polymer, prepolymer, or oligomer derived from a hydrocarbon resin having a structure defined by formula (A3)

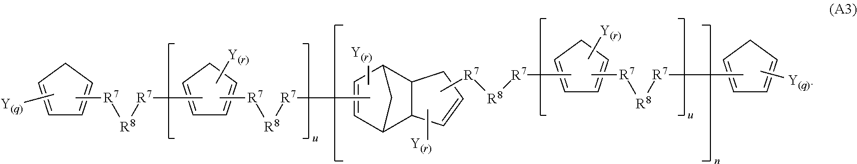

In one embodiment, the hydrocarbon resin composition (HRC) comprises at least (A1) and (A2).

In one embodiment the hydrocarbon resin composition (HCR) comprises at least two different hydrocarbon resin having a structure as defined by formula (A2). These at least two different hydrocarbon resin differ at least in one moiety (R³, R⁴, R⁵, R⁶, X, p, r, and w) and may be denoted as (A2-X) and (A2-Y). Suitably, the at least two different hydrocarbon resin may be a hydrocarbon resin having a structure as defined by formula (A2-1) and a hydrocarbon resin having a structure as defined by formula (A2-3). If present, the at least two different hydrocarbon resin (A2-X) and (A2-Y) generally have a weight ratio of 100:1 to 1:100, preferably of 50:1 to 1:15, more preferably of 10:1 to 1:10 such as of 4:1 to 1:4, or of 3:1 to 1:3, or of 2:1 to 1:2, or of 1.5:1 to 1:1.5, or of 1.2:1 to 1:1.2. In this connection, the hydrocarbon resin composition (HCR) may additionally comprises (A1).

In one embodiment, the hydrocarbon resin composition (HRC) comprises at least (A1) and a polymer, prepolymer, or oligomer derived from a hydrocarbon resin having a structure defined by formula (A3).

In one embodiment, the hydrocarbon resin composition (HRC) comprises at least (A2) and a polymer, prepolymer, or oligomer derived from a hydrocarbon resin having a structure defined by formula (A3).

In one embodiment, the hydrocarbon resin composition (HRC) comprises (A1), (A2), and a polymer, prepolymer, or oligomer derived from a hydrocarbon resin having a structure defined by formula (A3).

In one embodiment, the hydrocarbon resin composition (HCR) comprises (A1), (A2-X), (A2-Y), and a polymer, prepolymer, or oligomer derived from a hydrocarbon resin having a structure defined by formula (A3).

In one embodiment, the hydrocarbon resin having a structure as defined by formula (A1) and the hydrocarbon resin having a structure as defined by formula (A2) are present in the hydrocarbon resin composition (HRC) in a weight ratio of 100:1 to 1:100, preferably of 50:1 to 1:50, more preferably of 10:1 to 1:10 such as of 4:1 to 1:4, or of 3:1 to 1:3, or of 2:1 to 1:2, or of 1.5:1 to 1:1.5, or of about 1.2:1 to 1:1.2.

In one embodiment, the monomer, oligomer, prepolymer, and/or polymer being polymerizable by exposure to actinic radiation or light (B1) is present, preferably comprising reactive end groups selected from the group consisting of acrylates, methacrylates, olefins such as α-olefins, N-vinyls, acrylamides, methacrylamides, styrenics, epoxides, oxetanes, thiols, 1,3-dienes, vinyl halides, acrylonitriles, vinyl esters, maleimides, bisnadicimides, vinyl ethers, cyanate esters, bisbenzocyclobutenes, and mixtures thereof, more preferably comprising reactive end groups selected from the group consisting of acrylates, methacrylates, olefins, epoxides, oxetanes, maleimides, cyanate esters, bisbenzocyclobutenes, and mixtures thereof, and in particular selected from the group consisting of acrylates, methacrylates, olefins, epoxides, maleimides, cyanate esters, and mixtures thereof

In one embodiment, the monomer, oligomer, prepolymer, and/or polymer being polymerizable by exposure to actinic radiation or light (B1) is selected from the group consisting of difunctional epoxy acrylate oligomer, trimethylolpropane triacrylate, a diallylbisphenol A dicyanate ester, bisallylnadicimide 1,3-bis(citraconimidomethyl)benzene, copolymers of butadiene and styrene (e.g. having a molecular weight (Mn) of 1,000 to 1,000,000 g/mol), homopolymers of butadiene such as maleinized butadiene e.g. Ricon 130, and olefin and/or (meth)acrylate poly(p-phenylene oxide) (PPO) resin (e.g. SA-9000 or OPE).

Further suitable monomer, oligomer, prepolymer, and/or polymer being polymerizable by exposure to actinic radiation or light (B1) are above-outlined in more detail.

In one embodiment, the resin composition (RC) further comprises a monomer, oligomer, prepolymer, and/or polymer being polymerizable by exposure to actinic radiation or light (B2) different to (B1).

In one embodiment, (B2) comprises reactive end groups selected from the group consisting of acrylates, methacrylates, olefins, N-vinyls, acrylamides, methacrylamides, styrenics, epoxides, oxetanes, thiols, 1,3-dienes, vinyl halides, acrylonitriles, vinyl esters, maleimides, bisnadicimides, vinyl ethers, cyanate esters, bisbenzocyclobutenes, and mixtures thereof, preferably selected from the group consisting of acrylates, methacrylates, olefins, epoxides, oxetanes, maleimides, cyanate esters, bisbenzocyclobutenes, and mixtures thereof, and in particular selected from the group consisting of acrylates, methacrylates, olefins, epoxides, maleimides, cyanate esters, and mixtures thereof.

In one embodiment, the monomer, oligomer, prepolymer, and/or polymer being polymerizable by exposure to actinic radiation or light (B2) is selected from the group consisting of difunctional epoxy acrylate oligomer, trimethylolpropane triacrylate, a diallylbisphenol A dicyanate ester, bisallylnadicimide, 1,3-bis(citraconimidomethyl)benzene, copolymers of butadiene and styrene (e.g. having a molecular weight (Mn) of 1,000 to 1,000,000 g/mol), homopolymers of butadiene such as maleinized butadiene e.g. Ricon 130, and olefin and/or (meth)acrylate poly(p-phenylene oxide) (PPO) resin (e.g. SA-9000 or OPE).

In one embodiment, (B1) and (B2) have a weight ratio of 100:1 to 1:100, preferably of 5:1 to 1:5, or of 4:1 to 1:4, or of 3:1 to 1:3 or of 2:1 to 1:2, or of 1.5:1 to 1:1.5, or of about 1:1.

In one embodiment, (B1) comprises reactive end groups selected from the group consisting olefins and acrylates and (B2) comprises reactive cyanate ester end groups, preferably wherein (B1) is trimethylolpropane triacrylate and (B2) is a diallylbisphenol A dicyanate ester.

In one embodiment, the photo initiator is selected from the group consisting of radical initiator, Lewis acid catalyst, and mixtures thereof.

In one embodiment, wherein the radical initiator is selected from the group consisting of dialkyl peroxide, diacyl peroxide, azo compound, and mixtures thereof and/or the Lewis acid catalysts is selected from the group consisting of a cationic thermal acid generator, a cationic photo-acid generator, and mixtures thereof.

Preferred radical initiator and Lewis acid catalysts are above-outlined in more detail.

In one embodiment, the photo initiator is selected from the group consisting of camphor quinone; benzophenone, benzophenone derivatives, such as 2,4,6-trimethylbenzophenone, 2-methylbenzophenone, 3-methylbenzo-phenone, 4-methylbenzophenone, 2-methoxycarbonylbenzophenone 4,4′-bis(chloromethyl)-benzophenone, 4-chlorobenzophenone, 4-phenylbenzophenone, 3,3′-dimethyl-4-methoxy-benzophenone, [4-(4-methylphenylthio)phenyl]-phenylmethanone, methyl-2-benzoyl-benzoate, 3-methyl-4′-phenylbenzophenone, 2,4,6-trimethyl-4′-phenylbenzophenone, 4,4′-bis(dimethylamino)benzophenone, 4,4′-bis(diethylamino)benzophenone; thioxanthones, thioxanthone derivatives, polymeric thio-xanthones as for example OMNIPOL TX; ketal compounds, as for example benzyldimethyl-ketal (IRGACURE®651); acetophenone, acetophenone derivatives, for example α-hydroxy-cycloalkyl phenyl ketones or α-hydroxyalkyl phenyl ketones, such as for example 2-hydroxy-2-methyl-1-phenyl-propanone (DAROCUR® 1173), 1-hydroxy-cyclohexyl-phenyl-ketone (IRGACURE® 184), 1-(4-dodecylbenzoyl)-1-hydroxy-1-methyl-ethane, 1-(4-isopropylbenzoyl)-1-hydroxy-1-methyl-ethane, 1-[4-(2-hydroxyethoxy)-phenyl]-2-hydroxy-2-methyl-1-propan-1-one (IRGACURE® 2959); 2-hydroxy-1-{4-[4-(2-hydroxy-2-methyl-propionyl)-benzyl]-phenyl}-2-methyl-propan-1-one (IRGACURE® 127); 2-hydroxy-1-{4-[4-(2-hydroxy-2-methyl-propionyl)-phenoxy]-phenyl}-2-methyl-propan-1-one; dialkoxyacetophenones, α-hydroxy- or α-am-inoacetophenones, e.g., (4-methylthiobenzoyl)-1-methyl-1-morpholinoethane (IRGACURE® 907), (4-morpholinobenzoyl)-1-benzyl-1-dimethylaminopropane (IRGACURE® 369), (4-morpholinobenzoyl)-1-(4-methylbenzyl)-1-dimethylaminopropane (IRGACURE® 379), (4-(2-hydroxyethyl)aminobenzoyl)-1-benzyl-1-dimethylaminopropane), (3,4-dimethoxybenzoyl)-1-benzyl-1-dimethyl aminopropane; 4-aroyl-1,3-dioxolanes, benzoin alkyl ethers and benzyl ketals, e.g. dimethyl benzyl ketal, phenylglyoxalic esters and derivatives thereof, e.g., methyl α-oxo benzeneacetate, oxo-phenyl-acetic acid 2-(2-hydroxy-ethoxy)-ethyl ester, dimeric phenylglyoxalic esters, e.g. oxo-phenyl-acetic acid 1-methyl-2-[2-(2-oxo-2-phenyl-acetoxy)-propoxy]-ethyl ester (IRGACURE® 754); ketosulfones, e.g. ESACURE KIP 1001 M®; oxime-esters, e.g., 1,2-octanedione 1-[4-(phenylthio)phenyl]-2-(0-benzoyloxime) (IRGACURE® OXEOI), ethanone I-[9-ethyl-6-(2-methylbenzoyl)-9H-carbazol-3-yl]-1-(O-acetyloxime) (IRGACURE® OXE02), 9H-thioxanthene-2-carboxaldehyde 9-oxo-2-(0-acetyloxime), peresters, benzophenone tetracarboxylic peresters, monoacyl phosphine oxides, e.g. (2,4,6-trimethylbenzoyl)diphenylphosphine oxide (DAROCUR® TPO), ethyl(2,4,6 trimethylbenzoyl phenyl)phosphinic acid ester; bisacyl-phosphine oxides, e.g., bis(2,6-dimethoxy-benzoyl)-(2,4,4-trimethyl-pentyl)phosphine oxide, bis(2,4,6-trimethylbenzoyl)-phenylphosphine oxide (IRGACURE® 819), bis(2,4,6-trimethyl-benzoyl)-2,4-dipentoxyphenylphosphine oxide, trisacylphosphine oxides, halomethyltriazines, e.g., 2-[2-(4-methoxy-phenyl)-vinyl]-4,6-bis-trichloromethyl-[1,3,5]triazine, 2-(4-methoxy-phenyl)-4,6-bis-trichloromethyl-[1,3,5]triazine, 2-(3,4-dimethoxy-phenyl)-4,6-bis-trichlorome-thyl-[1,3,5]triazine, 2-methyl-4,6-bis-trichloromethyl-[1,3,5]triazine, hexaarylbisimidazole/co-initiators systems, e.g., ortho-chlorohexaphenyl-bisimidazole combined with 2-mercapto-benzthiazole, ferrocenium compounds, titanocenes, e.g., bis(cyclopentadienyl)-bis(2,6-difluoro-3-pyrryl-phenyl)titanium (IRGACURE® 784), bis(2,4,6-trimethylbenzoyl)-phenylphosphineoxide, bis-(4-dodecylphenyl)iodonium hexafluroantimonate in glycidyl ether, (sulfanediyldibenzene-4,1-diyl)bis(diphenylsulfonium) bis(hexafluoroantimonate) in digycidyl ether, ethyl phenyl(2,4,6-trimethylbenzoyl)phosphinate, 7-oxabicyclo[4.1.0]hept-3-ylmethyl 7-oxabicyclo[4.1.0]heptane-3-carboxylate, and mixtures thereof.

In one embodiment, the resin composition (RC) comprise at least 25 wt % such as at least 30 wt %, or at least 35 wt %, or at least 40 wt %, or at least 45 wt %, or at least 50 wt %, or at least 60 wt %, or at least 65 wt %, or at least 70 wt %, or at least 75 wt %, or at least 80 wt %, or at least 85 wt %, or at least 90 wt %, or at least 95 wt %, of the hydrocarbon resin composition, based on the total weight of the resin composition (RC). In one embodiment, the resin composition (RC) comprises up to 99.9 wt % such as up to 98 wt %, or up to 95 wt %, or up to 90 wt %, or up to 85 wt %, or up to 80 wt %, or up to 75 wt %, or up to 70 wt %, or up to 65 wt %, or up to 60 wt %, or up to 55 wt %, or up to 50 wt %, of the hydrocarbon resin composition, based on the total weight of the resin composition (RC).

In one embodiment, the resin composition (RC) comprises 30 to 99.9 wt % such as 35 to 80 wt %, or 30 to 50 wt %, or 35 to 75 wt %, or 45 to 75 wt %, or 50 to 80 wt %, or 50 to 84 wt %, of the hydrocarbon resin composition, based on the total weight of the resin composition (RC).

In another embodiment, the resin composition (RC) comprises 50 to 98 wt %, or 55 to 98 wt %, or 60 to 90 wt %, of the hydrocarbon resin composition, based on the total weight of the resin composition (RC).

In one embodiment, the resin composition (RC) comprises 7.5 to 69.99 wt % such as 19 to 64 wt %, or 10 to 40 wt %, or 19 to 59 wt %, or 20 to 40 wt %, or 7 to 30 wt %, or 7.5 to 25 wt %, of (B1), based on the total weight of the resin composition (RC).

In one embodiment, the resin composition (RC) comprises 7.5 to 25 wt % of (B2), based on the total weight of the resin composition (RC).

In one embodiment, the resin composition (RC) comprises 0.01 to 15 wt % such as 1 to 6 wt %, or 1 to 7 wt %, or 1 to 8 wt %, of the catalyst (C), based on the total weight of the resin composition (RC).

In one embodiment, the resin composition (RC) comprises
30 to 92 wt % of the hydrocarbon resin composition (HRC),
7.5 to 69.5 wt % of (B1), and
0.5 to 8 wt % of the photo initiator,
each wt % based on the total weight of the resin composition (RC).

In one embodiment, the resin composition (RC) further comprises a solvent (S1), preferably an organic solvent, more preferably selected from the group consisting of acetone, butanon, tetrahydrofuran, 2-methyl tetrahydrofuran, ethyl acetate, butyl acetate, toluene, xylene, dimethylformamide, N-methyl-2-pyrrolidone, dimethyl toluene, methyl ethyl ketone, methyl isobutyl ketone, dimethylacetamide, N-methylpyrrolidone, and mixtures thereof, and in particular selected from the group consisting of acetone, butanon, and mixtures thereof.

In one embodiment, the resin composition (RC) comprises
25 to 74 wt %, preferably 33 to 66 wt %, of the hydrocarbon resin composition,
25 to 74 wt %, preferably 33 to 66 wt %, of (B1), and
1 to 6 wt %, preferably 1 to 3 wt %, of the photo initiator,
each wt % based on the total weight of the resin composition (RC).

In one embodiment, the resin composition (RC) comprises
30 to 50 wt %, preferably 32 to 45 wt %, of the hydrocarbon resin composition,
10 to 40 wt %, preferably 20 to 30 wt %, of (B1),
1 to 7 wt %, preferably 2 to 6 wt %, of the photo initiator, and
20 to 45 wt %, preferably 30 to 40 wt %, of the solvent (S1),
each wt % based on the total weight of the resin composition (RC).

In one embodiment, the resin composition (RC) comprises
35 to 75 wt %, preferably 40 to 54 wt %, of the hydrocarbon resin composition,
19 to 59 wt %, preferably 25 to 35 wt %, of (B1),
1 to 8 wt %, preferably 3 to 7 wt %, of the photo initiator, and
5 to 25 wt %, preferably 10 to 20 wt %, of the solvent (S1),
each wt % based on the total weight of the resin composition (RC).

In one embodiment, the resin composition (RC) comprises
45 to 75 wt %, preferably 55 to 65 wt %, of the hydrocarbon resin composition,
20 to 40 wt %, preferably 25 to 35 wt %, of (B1),
1 to 8 wt %, preferably 2 to 6 wt %, of the photo initiator, and
1 to 15 wt %, preferably 4 to 10 wt %, of the solvent (S1),
each wt % based on the total weight of the resin composition (RC).

In one embodiment, the resin composition (RC) comprises
50 to 80 wt %, preferably 60 to 70 wt %, of the hydrocarbon resin composition,
7 to 30 wt %, preferably 8 to 20 wt %, of (B1),
1 to 6 wt %, preferably 2 to 5 wt %, of the photo initiator, and
7 to 30 wt %, preferably 8 to 20 wt %, of the solvent (S1),
each wt % based on the total weight of the resin composition.

In one embodiment, the resin composition (RC) comprises
50 to 84 wt %, preferably 60 to 82 wt %, of the hydrocarbon resin composition,
7.5 to 25 wt %, preferably 8 to 20 wt %, of the compound (B1),
7.5 to 25 wt %, preferably 8 to 20 wt %, of the compound (B2), and
1 to 8 wt %, preferably 2 to 6 wt %, of the photo initiator,
each wt % based on the total weight of the resin composition.

In one embodiment, the resin composition (RC) comprises 20 to 45 wt %, preferably 30 to 40 wt %, of the solvent (S1), based on the total weight of the resin composition (RC).

In one embodiment, the process further comprises the step of applying copper onto layer (L2).

As aforementioned, the invention relates in a sixth aspect to a pre-structured object obtained by the process according to the fifth aspect.

Particular embodiments (e.g. regarding the ingredients, amounts, moieties, and curing conditions) are already above-outlined in connection with the above aspects and shall hold for the pre-structured object, as well. In the following, particular embodiments of the pre-structured object are described in further detail. It is to be understood that each embodiment is relevant on its own as well as in combination with other embodiments.

In one embodiment, the pre-structured object is a part of a circuit board.

As aforementioned, the invention relates in a seventh aspect to the use of the resin composition according to the first aspect in the manufacturing of a printed circuit board, a photo-sensitive build up film, a Photo-dielectric, a Die Attach Paste/Adhesive, a Die Attach Film Adhesive, a Capillary Underfill, a Molded Underfill, a Molding Compound, a Liquid Encapsulant, a Redistribution Dielectric, a ramome, a radar structures, a satellite structure, a antennas such as cellular phone antennas, satellite phone antennas, a antennas for 5G communication devices, a 3D printed copper clad laminate, a Resin-Coated-Copper (RCC) Lamination Processes, a light printing (DLP), a continuous liquid interface printing (CLIP), a Stereolithography (SL), a high-density interconnect (HDI) substrate, an integrated circuit (IC), a part of an underfill adhesive composition, or an adhesive in oil & gas applications (pipeline repair).

Particular embodiments (e.g. regarding the ingredients, amounts, moieties, and curing conditions) are already above-outlined in connection with the above aspects and shall hold for the use, as well. In the following, particular embodiments of the use are described in further detail. It is to be understood that each embodiment is relevant on its own as well as in combination with other embodiments.

In one embodiment, the resin composition is initially used in the manufacturing of a cured resin (CR2) (as above-outlined in more detail). Said cured resin (CR2) is then preferably used in manufacturing of a printed circuit board, a radar structures, a satellite structure, a antennas such as cellular phone antennas, satellite phone antennas, a antennas for 5G communication devices, a 3D printed copper clad laminate, a Photo-dielectric, a Resin-Coated-Copper (RCC) Lamination Processes, a light printing (DLP), a continuous liquid interface printing (CLIP), a Stereolithography (SL), a high-density interconnect (HDI) substrate, an integrated circuit (IC), a part of an underfill adhesive composition, or an adhesive in oil & gas applications (pipeline repair).

As aforementioned, the invention relates in an eighth aspect to a kit comprising
1) a container (A) comprising
a resin composition (RC) comprising
a.1) a hydrocarbon resin composition (HRC) comprising a hydrocarbon resin derived from a structure as defined by formula

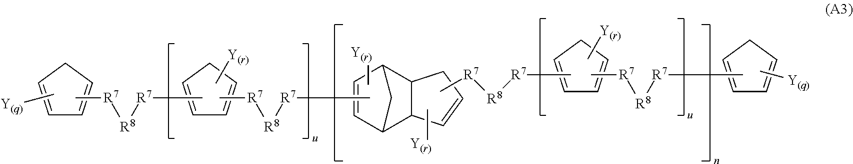

wherein
R⁷ is independently a methylene group (CH₂) or a methylene group substituted with one or more —CH₃ or halogen functionalities;
R⁸ is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety;
q is an integer of 1 to 5;
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
2) a container (B) comprising a monomer, oligomer, prepolymer, and/or polymer being polymerizable by exposure to actinic radiation or light (B1);
3) optionally a container (C); and
wherein the kit further comprises a catalyst (C), which is comprised in container (A), container (B), and/or container (C).

The kit can be used in methods of curing the resin composition (RC), e.g. in a method of manufacturing 3D-printed parts or pre-structured parts.

Particular embodiments (e.g. regarding the ingredients, amounts, moieties, and curing conditions) are already above-outlined in connection with the above aspects and shall hold for the kit, as well.

In the following, particular embodiments of the kit are described in further detail. It is to be understood that each embodiment is relevant on its own as well as in combination with other embodiments.

In one embodiment, the kit comprises
1) a container (A) comprising
a hydrocarbon resin composition comprising at least two of (A1) to (A3)
a.1) a hydrocarbon resin having a structure as defined by formula (A1)

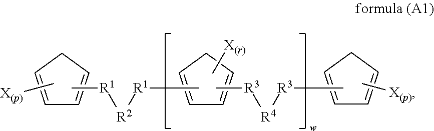

wherein
R¹ is independently a methylene group (CH₂) or a methylene group substituted with one or more —CH₃ or halogen,
R² is a bond or a substituted or unsubstituted C1-C20 alkylene,
R³ is independently a methylene group (CH₂) or a methylene group substituted with one or more —CH₃ or halogen,
R⁴ is independently a bond or a substituted or unsubstituted C1-C20 alkylene, C4-C20 aromatic group, or saturated or unsaturated C4-C20 cyclic group,
X is independently a functionality possessing at least one non-aromatic alkene, alkyne, C1-C14 alkyl, or an aromatic moiety,
p is independently an integer of 1 to 5,
r is independently 0 or an integer of 1 to 4, and
w is 0 or an integer of 1 to 50 and when w is 0, the bracket region represents a bond;
a.2) a hydrocarbon resin having a structure as defined by

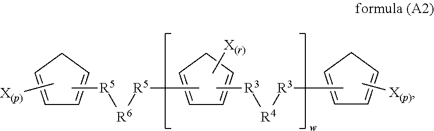

wherein
R³ is independently a methylene group (CH₂) or a methylene group substituted with one or more —CH₃ or halogen,
R⁴ is independently a bond or a substituted or unsubstituted C1-C20 alkylene, C4-C20 aromatic group, or saturated or unsaturated C4-C20 cyclic group,
R⁵ is independently a methylene group (CH₂) or a methylene group substituted with one or more —CH₃ or halogen,
R⁶ is a substituted or unsubstituted C4-C20 aromatic group or saturated or unsaturated C4-C20 cyclic group,
X is independently a functionality possessing at least one non-aromatic alkene, alkyne, C1-C14 alkyl, or an aromatic moiety,
p is independently an integer of 1 to 5,
r is independently 0 or an integer of 1 to 4, and
w is 0 or an integer of 1 to 50 and when w is 0, the bracket region represents a bond; and
a.3) a polymer, prepolymer, or oligomer derived from a hydrocarbon resin having a structure defined by formula

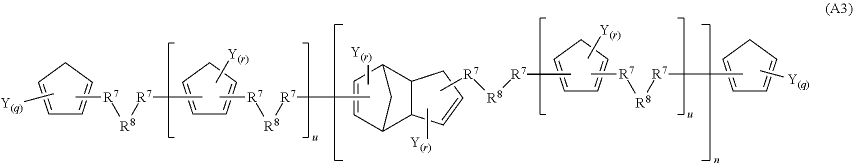

wherein
R⁷ is independently a methylene group (CH₂) or a methylene group substituted with one or more —CH₃ or halogen functionalities,
R^{a} is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety,
q is an integer of 1 to 5,
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
2) a container (B) comprising a monomer, oligomer, prepolymer, and/or polymer being polymerizable by exposure to actinic radiation or light (B1);
3) optionally a container (C); and
wherein the kit further comprises a catalyst (C), which is comprised in container (A), container (B), and/or container (C).

It will be obvious for a person skilled in the art that these embodiments and items only depict examples of a plurality of possibilities. Hence, the embodiments shown here should not be understood to form a limitation of these features and configurations. Any possible combination and configuration of the described features can be chosen according to the scope of the invention.

The present invention will be further illustrated by the following examples.

### EXAMPLES

### Chemicals

| Abbreviation | Chemical details | Purchased by |
|---|---|---|
| CN104 | difunctional epoxy acrylate oligomer | Sartomer |
| TMPTA | trimethylolpropane triacrylate | BASF |
| CL-100 | Diallylbisphenol A cyanate ester (CAS | Arxada |
| | 126791-29-5) | |
| Homide 100 | Bisallylnadicimide CAS 91865-54-2 | HOS |
| Perkalink900 | 1,3-bis(citraconimidomethyl)benzene | Lanxess |
| Ricon 100 | copolymer of butadiene and styrene | Cray Valley |
| ITX | Mixture of 2- and 4-isomer of Isopropyl- | Merck |
| | 9H-thioxanthen-9-on | |
| Omnirad 2022 | bis(2,4,6-trimethylbenzoyl)- | IGM |
| (also known as | phenylphosphineoxide | |
| Irgacure 2022) | | |
| Speedcure 937 | Bis-(4-dodecylphenyl)iodonium | Sartomer |
| | hexafluroantimonate in glycidyl ether | |
| Speedcure | (Sulfanediyldibenzene-4,1- | Sartomer |
| 976D | diyl)bis(diphenylsulfonium) | |
| | bis(hexafluoroantimonate)in digycidyl | |
| | ether | |
| Speedcure | Ethyl phenyl(2,4,6- | Sartomer |
| TPO-L | trimethylbenzoyl)phosphinate | |
| Uvicure S140 | low viscosity monofunctional oxetane | Sartomer |
| Uvicure S150 | 1,4-Bis[(3-ethyl-3- | Sartomer |
| | oxetanylmethoxy)methyl]benzene | |
| UviCure S105 | 7-oxabicyclo[4.1.0]hept-3-ylmethyl 7- | Sartomer |
| | oxabicyclo[4.1.0]heptane-3-carboxylate | |

Further, the following ingredients were used:
Ricon 130 (homopolymer of polybutadiene), Ricon 138 (homopolymer of polybutadiene), Ricon 152 (homopolymer of polybutadiene, Dry Liquid 70% Active), Ricon 153 (homopolymer of polybutadiene, Dry Liquid 65% Active), Ricon 156 (homopolymer of polybutadiene), Ricon 157 (homopolymer of polybutadiene), Ricon 181 (butadiene-styrene copolymer), Ricon 300 (liquid polybutadiene resin) Ricon 257 (styrene butadiene resin solution), (are available from Cray Valley
BMI-/Derivatives: Homide 126A (4,4′-Diallylether bisphenol A, CAS-No. 3739-67-1), Homide 127A (2,2′-Diallyl bisphenol A (DABA), CAS-No. 1745-89-7) and Homide 400 (Resin based on Biscitraconimide) are available form HOS Technik
BMI-5100 (3,3′-dimethyl-5,5′-diethyl-4,4′-diphenylmethane bismaleimide, CAS NO. 105391-33-1) are available from Dawei Kasei
Additional BMI may be selected from Homide 250 (bismaleimide resin, CAS-no. 26140-67-0), Homide 123 (Homide 123, CAS-No. 6422-83-9), Homide 121 (4,4′-Diphenylmethane-bismaleimide, CAS-No. 13676-54-5), and 2300 (phenylmethane maleimide, CAS NO. 67784-74-1).

BMPI-300 having the structure

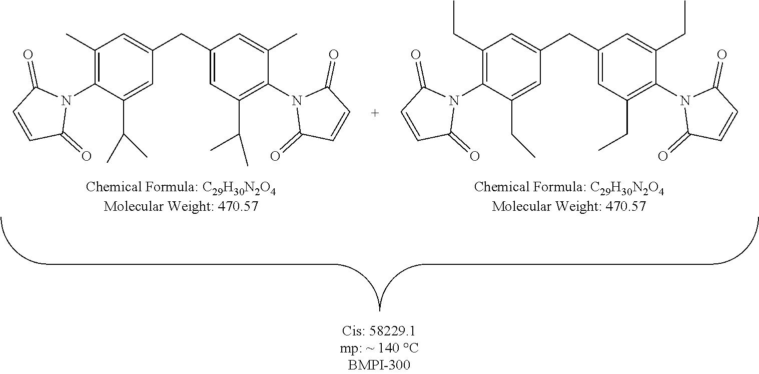 [SMILES: Cc1cc(Cc2cc(C)c(N3C(=O)C=CC3=O)c(C(C)C)c2)cc(C(C)C)c1N1C(=O)C=CC1=O ; CCc1cc(Cc2cc(CC)c(N3C(=O)C=CC3=O)c(CC)c2)cc(CC)c1N1C(=O)C=CC1=O]

& DETDA-BMI having the structure

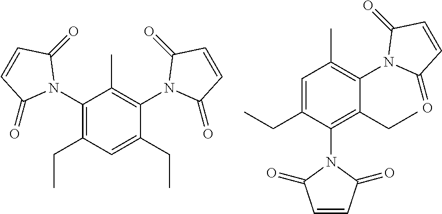

are available from Arxada
Epoxies: HP-7250 (Modified-Novolac type epoxide), HP-7200 (dicyclopentadiene type epoxide) and HP4710 (naphthalene type epoxide) are available from DIC Corporation
Epoxy: Epikote 828 (a medium viscosity liquid epoxy resin produced from bisphenol A resin and epichlorohydrin) is available from Westlake (former Hexion)
Cyanate Ester: DT-4000 (cyanate ester resin; further synonyms are polyphenolcyanate and triazine polymer), LECY (cyanate ester resin; further synonyms are 4,4′-ethylidendiphenyldicyanat, 1,1-bis(4-cyanatophenyl)ethan, bisphenol-E-dicyanate), PT-30 (cyanate ester resin; further synonyms are phenolic novolac cyanate ester resin, polyphenolcyanate, triazine polymer), CL-100 (crosslinking material which combines cyanate ester functionalities and reactive double bonds) are all available from Arxada
HTM-100 BT-Resin (bismaleimide triazine) available from Arxada
Catalyst: Speedcure 937 (bis-(4-dodecylphenyl)iodonium hexafluroantimonate in glycidyl ether) available from Arkema and Speedcure 976D ((Sulfanediyldibenzene-4,1-diyl)bis(diphenylsulfonium) bis(hexafluoroantimonate) in digycidyl ether) was used as well
Additional catalysts may be selected from 938 (bis-(4-t-butylphenyl)-iodonium hexafluorophosphate) and 939 (4-isopropyl-4′-methyldiphenyliodonium tetrakis (pentafluorophenyl)borate)
SA-9000 (poly phenylene oxide (PPO) telechelic copolymers) are available from Sabic
Divinylbenzol (DVB) is available from Aldrich and was used without further purification

### Material

FlackTek Speedmixer® DAC 1200-500
UV-B/UV-A 70 watt lamp

### Example 1

### Manufacturing of the Hydrocarbon Resin HC-100

Under nitrogen atmosphere 1900 mL toluene, 326 g 1,4-bis(chloromethyl) benzene and 70 g methyltributylammonium chloride were charged to a reactor and the suspension was cooled to about 8 °C. 625 g cyclopentadiene and 900 g potassium hydroxide were added while maintaining the temperature between about 8 to 10 °C. Additional 4020 g potassium hydroxide was added at the same temperature range. The reaction mixture was heated to about 20 °C and 428 g allyl chloride and 233 g benzyl chloride were added at a temperature of about 25 °C followed by the addition of 181 g 1,2-dichloroethane at the same temperature range. After complete addition, the reaction mixture was heated to about 50 °C and stirred at this temperature for about 1 h.

The mixture was heated to 70 °C for 1 h and washed with water and the solvent was removed by distillation (30 mbar/70 °C) to isolate the final product in a yield of 79%.

### HC-200 Synthetic Procedure

150 ml HC-100 was heated to 150 °C for ~3-7 h for prepolymerization. The prepolymerization was stopped, if resin viscosity reached ~100-500 mPa*s @82 °C.

### BCMB-164 Synthetic Procedure

1483 ml toluene, 404 g 4,4′-bis(chloromethyl)-1,1′-biphenyl and 61 g methyltributylammonium chloride was charged to a reactor and the suspension was cooled to about 8 °C. 600 g cyclopentadiene and 795 g potassium hydroxide (50% aq. solution) was added while maintaining the temperature between about 8 to 13 °C. Additional 3539 g potassium hydroxide (50% aq. solution) was dosed at the same temperature range. The reaction mixture was heated to about 20 °C and 377 g allyl chloride and 206 g benzyl chloride was added by parallel dosage at a temperature between about 20 and 25 °C followed by the addition of 159 g 1,2-dichloroethane at the same temperature range. After complete addition, the reaction mixture was heated to about 50 °C and stirred at this temperature for about 1 h.

The mixture was heated to 70 °C for 1 h and washed with water twice. Then the solvent was removed by distillation (30 mbar/70 °C) to isolate the final product in a yield of 64%.

### PXDC:BCMB(1:1)-170 Synthetic Procedure

1267 ml toluene, 123 g 1,4-bis(chloromethyl) benzene, 173 g 4,4′-bis(chloromethyl)-1,1′-biphenyl and 52 g methyltributylammonium chloride was charged to a reactor and the suspension was cooled to about 8 °C. 500 g cyclopentadiene and 679 g potassium hydroxide (50% aq. solution) was added while maintaining the temperature between about 8 to 13 °C. Additional 3025 g potassium hydroxide (50% aq. solution) was dosed at the same temperature range. The reaction mixture was heated to about 20 °C and 322 g allyl chloride and 176 g benzyl chloride was added by parallel dosage at a temperature between about 20 and 25 °C followed by the addition of 136 g 1,2-dichloroethane at the same temperature range. After complete addition, the reaction mixture was heated to about 50 °C and stirred at this temperature for about 1 h.

The mixture was heated to 70 °C for 1 h and washed with water twice. Then the solvent was removed by distillation (30 mbar/70 °C) to isolate the final product in a yield of 84%.

### TFB-(174) Synthetic Procedure

451 ml toluene, 1242 g 1,4-bis(bromomethyl)-2,3,5,6-tetrafluorobenzene and 51 g methyltributylammonium chloride was charged to a reactor and the suspension was cooled to about 8 °C. 450 g cyclopentadiene and 665 g potassium hydroxide (50% aq. solution) was added while maintaining the temperature between about 8 to 13 °C. Additional 2961 g potassium hydroxide (50% aq. solution) was dosed at the same temperature range. The reaction mixture was heated to about 20 °C and 315 g allyl chloride and 172 g benzyl chloride was added by parallel dosage at a temperature between about 20 and 25 °C followed by the addition of 133 g 1,2-dichloroethane at the same temperature range. After complete addition, the reaction mixture was heated to about 50 °C and stirred at this temperature for about 1 h.

The mixture was heated to 70 °C for 1 h and washed with water twice. Then the solvent was removed by distillation (30 mbar/70 °C) to isolate the final product in a yield of 47%.

BMBC-164, PXDC:BCMB (1:1)-170 and TFB-(174) can be prepolymerized in a similar was than HC-100.

### Formulations

### Example 2

In a 50 mL aluminum container was added 10 g of HC-100 and 0.3 g of Omnirad 2022. The mixture was mixed for 10 min at 2000 rpm via a FlackTek Speedmixer®.

| | Mass [g] | [wt %] |
|---|---|---|
| HC-100 | 10 | 97.1% |
| Omnirad | 0.3 | 2.9% |
| Total | 10.3 | 100% |

### Example 3

In a 50 mL aluminum container was added 10 g of HC-100, 0.3 g of SpeedCure 976D, 0.06 g of ITX and 0.5 g of technical grad acetone. The mixture was mixed for 10 min at 2000 rpm via a FlackTek Speedmixer®.

| | Mass [g] | [wt %] |
|---|---|---|
| HC-100 | 10 | 92.1% |
| SpeedCure 976D | 0.3 | 2.8% |
| ITX | 0.06 | 0.6% |
| Acetone | 0.5 | 4.6% |
| Total | 10.86 | 100% |

### Example 4: Catalyst Screening

In a 50 mL aluminum container was added 10 g of HC-100, 0.4 g of the respective Catalyst XY (see below table), 0.1 g of ITX and 0.5 g of technical grad acetone. The mixture was mixed for 5 min at 2000 rpm via a FlackTek Speedmixer®.
(wt %: Catalyst 3.8 wt %*, sensitizer 0.95 wt %*, *calculated on neat resin, without acetone)

| | Mass [g] | [wt %] |
|---|---|---|
| HC-100 | 10 | 90.9% |
| Catalyst XY | 0.4 | 3.6% |
| ITX | 0.1 | 0.9% |
| Acetone | 0.5 | 4.5% |
| Total | 11 | 100% |

### Tested Catalysts XY:

| Catalysts | Chemical type | Reaction type |
|---|---|---|
| UviCure S105 | Epoxid | Cationic |
| UviCure S140 | Oxetane | Cationic |
| UviCure S150 | Oxetane | Cationic |
| SpeedCure TPO-L | Phosphine Oxide | Radical |
| SpeedCure 976D | triarylsulfonium | Cationic |
| | hexafluoroantimonate | |
| SpeedCure 937 | iodonium hexafluoroantimonate | Cationic |

Overall, Speedcure 937 is the fastest of the above-outlined catalysts. It should be noted that Speedcure TPO-L works well in combination with acrylates (not disclosed). However, the addition of acrylates is not mandatory. For ITX, a solvent for dilution into Resin is recommended (acetone and butanone work well).

### Example 5: TMPTA (Acrylate Functionality)+HC-100

In a 50 mL aluminum container was added 5.07 g TMPTA, 2.67 g HC-100 and 0.19 g SpeedCure TPO-L. The mixture was mixed for 5 min at 2000 rpm via a FlackTek Speedmixer®.

| | Mass [g] | [wt %] |
|---|---|---|
| TMPTA | 5.07 | 63.9% |
| HC-100 | 2.67 | 33.7% |
| Speedcure TPO-L | 0.19 | 2.4% |
| Total | 7.93 | 100.0% |

### Example 6: TMPTA (Acrylate Functionality)+HC-100

In a 50 mL aluminum container was added 5.07 g TMPTA, 5.2 g HC-100 and 0.19 g SpeedCure TPO-L. The mixture was mixed for 5 min at 2000 rpm via a FlackTek Speedmixer®.

| | Mass [g] | [wt %] |
|---|---|---|
| TMPTA | 5.07 | 48.5% |
| HC-100 | 5.2 | 49.7% |
| Speedcure TPO-L | 0.19 | 1.8% |
| Total | 10.46 | 100.0% |

### Example 7: Ricon 100 (Copolymer Butadiene and Styrene)+HC-100

In a 50 mL aluminum container was added 1.48 g Ricon 100, 2.28 g HC-100 and 2 g technical grade butanon. The mixture was mixed for 5 min at 2000 rpm via a FlackTek Speedmixer®.

2 g of that mixture were added to a 20 mL vial with 0.09 g SpeedCure 937 and 0.01 g ITX. The mixture was mixed for 5 min at 2000 rpm via a FlackTek Speedmixer®.

| | Mass [g] | [wt %] |
|---|---|---|
| HC-100 | 0.79 | 37.7% |
| Ricon 100 | 0.51 | 24.5% |
| Butanon | 0.69 | 33.0% |
| ITX | 0.01 | 0.5% |
| Speedcure 937 | 0.09 | 4.3% |
| Total | 2.1 | 100% |

### Example 8: CN104 (Epoxy Functionality)+HC-100

In a 50 mL aluminum container was added 2.2 g CN104, 3.62 g HC-100, 1 g technical grade acetone, 0.32 g SpeedCure 937 and 0.07 g ITX. The mixture was mixed for 5 min at 2000 rpm via a FlackTek Speedmixer®.

| | Mass [g] | [wt %] |
|---|---|---|
| HC-100 | 3.62 | 50.2% |
| CN104 | 2.20 | 30.5% |
| Acetone | 1.00 | 13.9% |
| ITX | 0.32 | 4.4% |
| Speedcure 937 | 0.07 | 1.0% |
| Total | 7.21 | 100% |

### Example 9: CN104 (Epoxy Functionality)+HC-100

In a 50 mL aluminum container was added 2.3 g CN104, 3.74 g HC-100, 1 g technical grade acetone and 0.36 g SpeedCure TPO-L. The mixture was mixed for 5 min at 2000 rpm via a FlackTek Speedmixer®.

| | Mass [g] | [wt %] |
|---|---|---|
| HC-100 | 3.74 | 50.5% |
| CN104 | 2.30 | 31.1% |
| Acetone | 1.00 | 13.5% |
| Speedcure TPO-L | 0.36 | 4.9% |
| Total | 7.4 | 100% |

### Example 10: CL-100 (Cyanate Functionality)+HC-100

In a 20 mL glass vial was added 2.0 g CL-100, 4.0 g HC-100, 0.5 g technical grade acetone, 0.06 g ITX and 0.24 g SpeedCure 937. The mixture was mixed for 5 min at 2000 rpm via a FlackTek Speedmixer®.

| | Mass [g] | [wt %] |
|---|---|---|
| HC-100 | 4.00 | 58.8% |
| CL-100 | 2.00 | 29.4% |
| Acetone | 0.50 | 7.4% |
| ITX | 0.06 | 0.9% |
| Speedcure 937 | 0.24 | 3.5% |
| Total | 6.8 | 100% |

### Example 11: Perkalink900 (Imid Functionality)+HC-100

In a 20 mL glass vial was added 1 g Perkalink900, 5.0 g HC-100. The mixture was heated to 100 °C and mixed for 5 min at 2000 rpm via a FlackTek Speedmixer®. Afterward was added 1 g of butanon, 0.31 g SpeedCure 937 and 0.06 g ITX to the mixture. The mixture was mixed for 5 min at 2000 rpm via a FlackTek Speedmixer®.

| | Mass [g] | [wt %] |
|---|---|---|
| HC-100 | 5.00 | 67.8% |
| Perkalink900 | 1.00 | 13.6% |
| Butanon | 1.00 | 13.6% |
| ITX | 0.06 | 0.8% |
| Speedcure 937 | 0.31 | 4.2% |
| Total | 7.37 | 100% |

### Example 12: Homide100 (Imid Functionality)+HC-100

In a 50 mL aluminum container was added 1 g Homide 100, 5.0 g HC-100. The mixture was heated to 100 °C and mixed for 10 min at 2000 rpm via a FlackTek Speedmixer®. Afterward 1 g of butanone was added. The mixture was heated to 60 °C and mixed for 10 min at 2000 rpm via a FlackTek Speedmixer®. Finally, 0.24 g SpeedCure 937 and 0.06 g ITX were added to the mixture.

The mixture was mixed for 5 min at 2000 rpm via a FlackTek Speedmixer®.

| | Mass [g] | [wt %] |
|---|---|---|
| HC-100 | 5.00 | 68.5% |
| Homide 100 | 1.00 | 13.7% |
| Butanone | 1.00 | 13.7% |
| ITX | 0.06 | 0.8% |
| Speedcure 937 | 0.24 | 3.3% |
| Total | 7.3 | 100% |

### Example 13: TMPTA (Acrylate Functionality)+HC-100

In a 20 mL glass vial was added 0.5 g TMPTA, 5.5 g HC-100 and 0.24 g SpeedCure TPO-L. The mixture was mixed for 5 min at 2000 rpm via a FlackTek Speedmixer®.

| | Mass [g] | [wt %] |
|---|---|---|
| HC-100 | 5.50 | 88.1% |
| TMPTA | 0.50 | 8.0% |
| Speedcure TPO-L | 0.24 | 3.8% |
| Total | 6.24 | 100% |

### Example 14: TMPTA (Acrylate Functionality)+CL-100 (Cyanate Functionality)+HC-100

In a 20 mL glass vial was added 0.5 g TMPTA, 5 g HC-100, 0.5 g CL-100 and 0.24 g SpeedCure TPO-L. The mixture was mixed for 5 min at 2000 rpm via a FlackTek Speedmixer®.

| | Mass [g] | [wt %] |
|---|---|---|
| HC-100 | 5.00 | 80.1% |
| TMPTA | 0.50 | 8.0% |
| CL-100 | 0.50 | 8.0% |
| Speedcure TPO-L | 0.24 | 3.8% |
| Total | 6.24 | 100% |

### Example 15: TMPTA (Acrylate Functionality)+CL-100 (Cyanate Functionality)+HC-100

In a 20 mL glass vial was added 1 g TMPTA, 4 g HC-100, 1 g CL-100 and 0.24 g SpeedCure TPO-L. The mixture was mixed for 5 min at 2000 rpm via a FlackTek Speedmixer®.

| | Mass [g] | [wt %] |
|---|---|---|
| HC-100 | 4.00 | 64.1% |
| TMPTA | 1.00 | 16.0% |
| CL-100 | 1.00 | 16.0% |
| Speedcure TPO-L | 0.24 | 3.8% |
| Total | 6.24 | 100% |

### UV-Curing Process

Two to three drops of the mixture according to Examples 2 to 15, respectively, were spread on a glass surface and with the help of a drawdown bar a layer of about 200 μm thickness was created. The film was then irradiated for about 30 to about 60 min with a 70 watt UV-B UV-A lamp to obtain a solid film. The solid film, could not be removed any more by a solvent combination of water and acetone.

### Mixtures

Liquid resins with similar viscosity as HC-100 mix well with it (e.g. LECY and CL-100). Solids and high viscous resins are recommended to be melted with HC-100 together and dissolved with solvent. Without solvent phase separation or precipitation may occur.

The above-outlined UV-Curing Process was applied on the mixtures according to Table 1 to obtain Tg values in range of 100 to 250 °C and good electrical performance (Dk<3 and Df<0.004 for all examples). The resins H-200, BOMB-164, PXDC:BCMB (1:1)-170 and TFB-(174) (and analogoues prepolymers) can be applied, as well.

A Split-Cylinder Resonator (SR) method was used for the electrical performance. The permittivity er and loss tangent tan δ (Dk and Df properties) are obtained and calculate with Agilent E8361A Network Analyzer. The results are according to the standard method IPC TM-650 2.5.5.13.

The compositions ingredients and the results are shown in Table 1 below:

TABLE 1
Tg values of parts; Speedcure 937 was used as catalyst;
Tg were determined by Thermal Mechanical Analysis (TMA).

| Cyclopentadien | Thermoset | Ratio | Catalyst | Tg |
|---|---|---|---|---|
| resin | resin | [w %] | [w %] | [°C] |
| HC-100 | Ricon 100 | 80:20 | 2-3 | 130/250* |
| HC-100 | Ricon 130 | 80:20 | 2-3 | 100/250* |
| HC-100 | Ricon 138 | 80:20 | 2-3 | 135/250* |
| HC-100 | Ricon 152 | 80:20 | 2-3 | 140/250* |
| HC-100 | Ricon 153 | 80:20 | 2-3 | 115/250* |
| HC-100 | Ricon 181 | 80:20 | 2-3 | 150/250* |
| HC-100 | Ricon 300 | 80:20 | 2-3 | 150/250* |
| HC-100 | Ricon 257 | 80:20 | 2-3 | 230 |
| HC-100 | Ricon 257 | 85:15 | 2-3 | 230 |
| HC-100 | BMPI-300 | 90:10 | 2-3 | 280 |
| HC-100 | BMPI-300 | 80:20 | 2-3 | 280 |
| HC-100 | BMI-5100 | 90:10 | 2-3 | 280 |
| HC-100 | BMI-5100 | 80:20 | 2-3 | 280 |
| HC-100 | DETDA-BMI | 90:10 | 2-3 | 270 |
| HC-100 | DETDA-BMI | 80:20 | 2-3 | 270 |
| HC-100 | Homide 100 | 90:10 | 2-3 | 270 |
| HC-100 | Homide 100 | 80:20 | 2-3 | 270 |
| HC-100 | Homide 400 | 90:10 | 2-3 | 230 |
| HC-100 | Homide 400 | 80:20 | 2-3 | 230 |
| HC-100 | Homide 126A | 80:20 | 2-3 | 200 |
| HC-100 | HP-7250 | 95:5 | 1-3 | 230 |
| HC-100 | HP-7200 | 75:25 | 1-3 | 127/245* |
| HC-100 | Epikote 828 | 75:25 | 1-3 | 200 |
| HC-100 | HP-7250/ | 70:25:5 | 1-3 | 160/245* |
| | Homide127A | | | |
| HC-100 | SA-9000 | 80:20 | 1-3 | 210** |
| HC-100 | LECY | 90:10 | 0-0.5 | 200 |
| HC-100 | HTM-100 | 90:10 | 0-0.5 | 210 |
| HC-100 | PT-30 | 90:10 | 0-0.5 | 220 |
| HC-100 | DT-4000 | 90:10 | 0-0.5 | 170 |
| HC-100 | DT-4000 | 25:75 | 0-0.5 | 150 |
| HC-100 | CL-100 | 90:10 | 0-0.5 | 205 |
| HC-100 | DVB | 90:10 | 1-3 | 230 |

*Two Tg's obtained
**Tg determination by sandwich method (sample between two quartz plates)

### Example 16: Thermal Curing of PXDC:BCMB(1:1)-170

| | | |
|---|---|---|
| 53.39 | (PXDC:BCMB(1:1) (batch 170) | 3.00 |
| | was combined with | |
| 1.65 | Speedcure 937 | 3% |
| | and mixed in a speedmixer for 1 min at | |
| | 2000 RPM | |

Cure Cycle:
2 h 100 °C, 100-120 °C, 2 h 120 °C, 120-150 °C,
2 h 150 °C, 150-230 °C, 2 h, open cool down

→ Tg(TMA) = 249 °C

### Example 17: Thermal Curing of TFB-174

| | | |
|---|---|---|
| 53.39 | TFB (batch 174) was | 3.04 |
| | combined with | |
| 1.65 | Speedcure 937 | 3% |
| | and mixed in a speedmixer for 1 min at | |
| | 2000 RPM | |

Cure Cycle:
2h 100 °C, 100-120 °C, 2h 120 °C, 120-150 °C,
2h 150 °C, 150-230 °C, 2h, open cool down

→ Tg(TMA) = 257 °C

The above component combinations are well mixable and the resin compositions are well workable due to a suitable viscosity. In addition, as can be derived from the above table, the resin compositions provide a high Tg. Thus, the resin compositions are particularly suitable for 3D printing and pre-structuring applications.

1. A resin composition comprising
a) 20 to 99.99 wt % of a hydrocarbon resin composition comprising at least two of (A1) to (A3)
a.1) a hydrocarbon resin having a structure as defined by formula (A1) 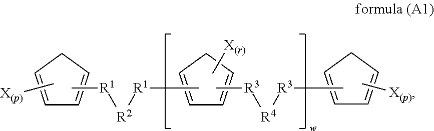
wherein
R¹ is independently a methylene group (CH₂) or a methylene group substituted with one or more —CH₃ or halogen,
R² is a bond or a substituted or unsubstituted C1-C20 alkylene,
R³ is independently a methylene group (CH₂) or a methylene group substituted with one or more —CH₃ or halogen,
R⁴ is independently a bond or a substituted or unsubstituted C1-C20 alkylene, C4-C20 aromatic group, or saturated or unsaturated C4-C20 cyclic group,
X is independently a functionality possessing at least one non-aromatic alkene, alkyne, C1-C14 alkyl, or an aromatic moiety,
p is independently an integer of 1 to 5,
r is independently 0 or an integer of 1 to 4, and
w is 0 or an integer of 1 to 50 and when w is 0, the bracket region represents a bond;
a.2) a hydrocarbon resin having a structure as defined by 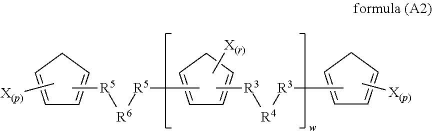
wherein
R³ is independently a methylene group (CH₂) or a methylene group substituted with one or more —CH₃ or halogen,
R⁴ is independently a bond or a substituted or unsubstituted C1-C20 alkylene, C4-C20 aromatic group, or saturated or unsaturated C4-C20 cyclic group,
R⁵ is independently a methylene group (CH₂) or a methylene group substituted with one or more —CH₃ or halogen,
R⁶ is a substituted or unsubstituted C4-C20 aromatic group or saturated or unsaturated C4-C20 cyclic group,
X is independently a functionality possessing at least one non-aromatic alkene, alkyne, C1-C14 alkyl, or an aromatic moiety,
p is independently an integer of 1 to 5,
r is independently 0 or an integer of 1 to 4, and
w is 0 or an integer of 1 to 50 and when w is 0, the bracket region represents a bond;
and
a.3) a polymer, prepolymer, or oligomer derived from a hydrocarbon resin having a structure defined by formula (A3) 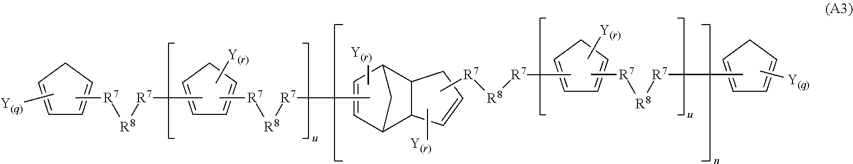
wherein
R⁷ is independently a methylene group (CH₂) or a methylene group substituted with one or more —CH₃ or halogen functionalities,
R⁸ is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety,
q is an integer of 1 to 5,
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
b) optionally 4.9 to 79.99 wt % of a monomer, oligomer, prepolymer, and/or polymer being polymerizable by exposure to actinic radiation or light (B1); and
c) 0.01 to 15 wt % of a catalyst (C),
each wt % based on the total weight of the resin composition.

2. The resin composition according to claim 1, wherein
X and/or Y is independently vinylbenzyl, propenylbenzene, ethenylbenzene, (methyl)ethenylbenzene, styrenyl, allyl, propargyl, butenyl, or benzyl, preferably independently allyl or benzyl.

3. The resin composition according to claim 1, wherein
R¹, R³, R⁵, and R⁷ are a methylene group (CH₂) and/or
R⁴ and R⁸ are independently a bond, a substituted or unsubstituted C6 aromatic group, a substituted or unsubstituted C10 aromatic group, or a substituted or unsubstituted C12 aromatic group.

4. The resin composition according to claim 1, wherein
R² is a bond or a C1-C10 alkylene, preferably a bond or a C1-C5 alkylene, and in particular a bond and/or
R⁶ is a substituted or unsubstituted C4-C18 aromatic group or a C4-C16 saturated or unsaturated cyclic group, preferably a substituted or unsubstituted C4-C16 aromatic group or a C4-C10 saturated or unsaturated cyclic group, more preferably a substituted or unsubstituted C6 aromatic group, a substituted or unsubstituted C10 aromatic group, a substituted or unsubstituted C12 aromatic group, a substituted or unsubstituted C13 aromatic group, a substituted or unsubstituted C14 aromatic group, a C5 saturated cyclic group, or a C6 saturated cyclic group, and in particular a substituted or unsubstituted C6 aromatic group, a substituted C10 aromatic group, or a substituted or unsubstituted C12 aromatic group.

5. The resin composition according to claim 1, wherein the hydrocarbon resin composition comprises (A2), wherein R⁶ is a substituted C6 aromatic group or a substituted or unsubstituted C12 aromatic group,
preferably wherein R⁵ is a methylene group (CH₂),
more preferably wherein the hydrocarbon resin composition comprises
a.2) a hydrocarbon resin having a structure as defined by formula (A2-2) 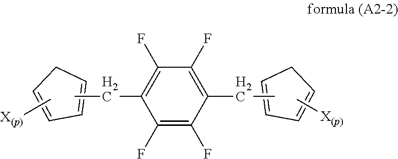
and/or
a hydrocarbon resin having a structure as defined by formula (A2-3)

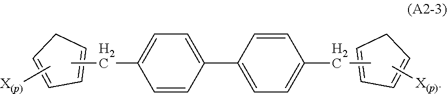

6. The resin composition according to claim 1, wherein
w is 0 or an integer of 1 to 20, preferably wherein w is 0 or an integer of 1 to 5, and in particular wherein w is 0; and/or
p is an integer of 1 to 4, preferably of 1 to 3, more preferably of 1 or 2, and in particular 1; and/or
r is independently 0 or an integer of 1 to 3, more preferably 0, 1, or 2, and in particular 0 or 1.

7. The resin composition according to claim 1, further comprising a monomer, oligomer, prepolymer, and/or polymer being polymerizable by exposure to actinic radiation or light (B2) different to (B1), preferably wherein (B1) and (B2) have a weight ratio of 100:1 to 1:100, preferably of 5:1 to 1:5.

8. The resin composition according to claim 1, wherein the catalyst is a photo initiator, preferably selected from the group consisting of radical initiator, Lewis acid catalyst, and mixtures thereof, more preferably wherein the radical initiator is selected from the group consisting of dialkyl peroxide, diacyl peroxide, azo compound, and mixtures thereof and/or the Lewis acid catalysts is selected from the group consisting of a cationic thermal acid generator, a cationic photo-acid generator, and mixtures thereof.

9. The resin composition according to claim 1, further comprising a solvent (Si), preferably an organic solvent, more preferably selected from the group consisting of acetone, butanon, tetrahydrofuran, 2-methyl tetrahydrofuran, ethyl acetate, butyl acetate, toluene, xylene, dimethylformamide, N-methyl-2-pyrrolidone, dimethyl toluene, methyl ethyl ketone, methyl isobutyl ketone, dimethylacetamide, N-methylpyrrolidone, and mixtures thereof and in particular selected from the group consisting of acetone, butanon, and mixtures thereof.

10. The resin composition according to claim 1, wherein the monomer, oligomer, prepolymer, and/or polymer being polymerizable by exposure to actinic radiation or light (B1) comprises reactive end groups selected from the group consisting of acrylates, methacrylates, olefins, N-vinyls, acrylamides, methacrylamides, styrenics, epoxides, oxetanes, thiols, 1,3-dienes, vinyl halides, acrylonitriles, vinyl esters, maleimides, bisnadicimides, vinyl ethers, cyanate esters, bisbenzocyclobutenes, and mixtures thereof, preferably selected from the group consisting of acrylates, methacrylates, olefins, epoxides, oxetanes, maleimides, cyanate esters, bisbenzocyclobutenes, and mixtures thereof, and in particular selected from the group consisting of acrylate, methacrylates, olefins, epoxides oxetanes, maleimides, cyanate esters, and mixtures thereof, and/or
wherein the monomer, oligomer, prepolymer, and/or polymer being polymerizable by exposure to actinic radiation or light (B2) comprises reactive end groups selected from the group consisting of acrylates, methacrylates, olefins, N-vinyls, acrylamides, methacrylamides, styrenics, epoxides, oxetanes, thiols, 1,3-dienes, vinyl halides, acrylonitriles, vinyl esters, maleimides, bisnadicimides, vinyl ethers, cyanate esters, bisbenzocyclobutenes, and mixtures thereof, preferably selected from the group consisting of acrylates, methacrylates, olefins, epoxides, oxetanes, maleimides, cyanate esters, bisbenzocyclobutenes, and mixtures thereof, and in particular selected from the group consisting of acrylates, methacrylates, olefins, epoxides, oxetanes, maleimides, cyanate esters, and mixtures thereof.

11. (canceled)

12. (canceled)

13. (canceled)

14. A process for manufacturing a pre-structured object, the process comprising the steps of
a) providing a resin composition (RC) comprising
a.1) a hydrocarbon resin composition (HRC) comprising a hydrocarbon resin derived from a structure as defined by formula (A3) 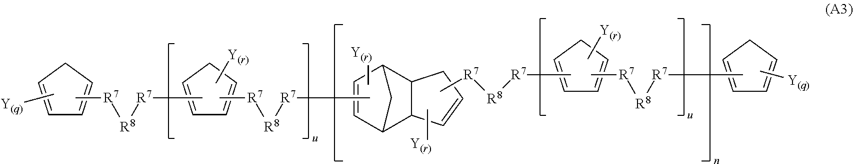
wherein
R⁷ is independently a methylene group (CH₂) or a methylene group substituted with one or more —CH₃ or halogen functionalities;
R⁸ is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety;
q is an integer of 1 to 5;
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
a.2) optionally a monomer, oligomer, prepolymer, and/or polymer being polymerizable by exposure to actinic radiation or light (B1); and
a.3) a photo initiator;
b) forming a resin composition layer having a thickness of 5 to 800 μm from the resin composition (RC);
c) irradiating the resin composition layer by means of a photomask providing a layer (L1), which at 25 °C it not soluble in a mixture of water and acetone;
d) washing the layer (L1) with a solvent (S2); and
e) curing the layer (L1) providing a layer (L2) having a Tg (determined by Tg onset via TMA measurement) of more than 150 °C.

15. The process according to claim 14, wherein the forming step b) provides a resin composition layer having a thickness of 20 to 600 μm, preferably of 50 to 500 μm, more preferably of 80 to 400 μm, still more preferably of 100 to 350 μm, and in particular of 120 to 250 μm and/or
wherein the forming step b) is conducted by spreading out the resin composition (RC), preferably on a substrate.

16. The process according to claim 14, wherein the photomask comprises UV-impermeable and UV-permeable parts; and/or
wherein the irradiating step c) is conducted with UV-Vis light, preferably having a wavelength of 10 to 500 nm, more preferably of 100 to 450 nm, and in particular of 280 to 400 nm; and/or
wherein the irradiating step c) is conducted for 1 second to 1 hour, preferably for 5 seconds to 30 minutes, and in particular for 15 seconds to 15 minutes.

17. The process according to claim 14, wherein the layer (L2) has a Tg (determined by Tg onset via TMA measurement) of more than 150 to 400 °C, preferably of 160 to 300 °C, and in particular of 180 to 260 °C.

18. The process according to claim 14, wherein the solvent (S2) is selected from the group consisting of cyclohexane, ethyl acetate, butyl acetate, toluene, methyl ethyl ketone, xylenes, N-methyl pyrrolidone, dimethylformamide, dichloromethane, acetonitrile, acetone, dimethyl sulfoxide, tetrahydrofuran, water, and mixtures thereof, preferably selected from the group consisting of water, acetone, and mixtures thereof and/or
wherein the layer (L1) is at 25 °C and ambient pressure not soluble in a solvent selected from the group consisting of cyclohexane, ethyl acetate, butyl acetate, toluene, methyl ethyl ketone, xylenes, N-methyl pyrrolidone, dimethylformamide, dichloromethane, acetonitrile, acetone, dimethyl sulfoxide, tetrahydrofuran, water, and mixtures thereof.

19. The process according to claim 14, wherein curing the layer (L1) in step e) is conducted thermally, preferably by heating the layer (L1) to 80 to 400 °C, preferably to 100 to 300 °C, more preferably to 120 to 250 °C and/or
wherein the layer (L1) in step e) is cured for 0.5 to 10 hours, preferably for 1 to 5 hours, more preferably for 2 to 4 hours.

20. The process according to claim 14, wherein the resin composition (RC) corresponds to the resin composition according to any one of claims 1 to 10.

21. A pre-structured object obtained by the process according to claim 14.

22. Use of the resin composition according to claim 1 in the manufacturing of a printed circuit board, a photo-sensitive build up film, a Die Attach Paste/Adhesive, a Photo-dielectric, a Die Attach Film Adhesive, a Capillary Underfill, a Molded Underfill, a Molding Compound, a Liquid Encapsulant, a Redistribution Dielectric, a ramome, a radar structures, a satellite structure, a antennas such as cellular phone antennas, satellite phone antennas, a antennas for 5G communication devices, a 3D printed copper clad laminate, a Resin-Coated-Copper (RCC) Lamination Processes, a light printing (DLP), a continuous liquid interface printing (CLIP), a Stereolithography (SL), a high-density interconnect (HDI) substrate, an integrated circuit (IC), a part of an underfill adhesive composition, or an adhesive in oil & gas applications (pipeline repair).

23. A kit comprising
1) a container (A) comprising
a resin composition (RC) comprising
a.1) a hydrocarbon resin composition (HRC) comprising a hydrocarbon resin derived from a structure as defined by formula (A3) 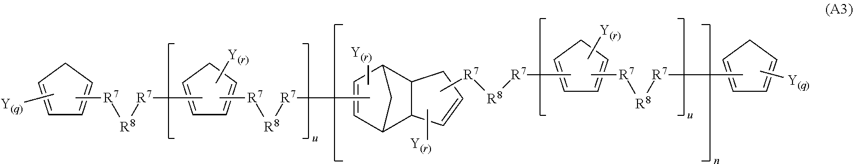
wherein
R⁷ is independently a methylene group (CH₂) or a methylene group substituted with one or more —CH₃ or halogen functionalities;
R⁸ is independently a bond or a straight-chain or branched, linear or cyclic, saturated or unsaturated, substituted or unsubstituted, aliphatic or aromatic group having between 1 and 20 carbon atoms,
Y is independently a functionality possessing at least one non-aromatic alkene, alkyne, C1-C14-alkyl, or an aromatic moiety;
q is an integer of 1 to 5;
r is independently 0 or an integer of 1 to 4,
u is independently 0, or an integer greater than or equal to 1, when u is 0, the bracket region represents a bond, and
n is 0 or an integer greater than or equal to 1, when n is 0, the bracket region represents a bond;
2) a container (B) comprising a monomer, oligomer, prepolymer, and/or polymer being polymerizable by exposure to actinic radiation or light (B1);
3) optionally a container (C); and
wherein the kit further comprises a catalyst (C), which is comprised in container (A), container (B), and/or container (C).
